(19) United States
(12) Patent Application Publication
(10) Pub. No.: US 2007/0190675 A1
(43) Pub. Date: Aug. 16, 2007

(54) MANUFACTURING METHOD OF DISPLAY DEVICE

(75) Inventors: Shunpei YAMAZAKI, Tokyo (JP); Shinobu FURUKAWA, Atsugi (JP); Masafumi MORISUE, Sagamihara (JP); Gen FUJII, Sagamihara (JP)

Correspondence Address: FISH & RICHARDSON P.C., P.O. BOX 1022, MINNEAPOLIS, MN, 55440-1022, US

(73) Assignee: SEMICONDUCTOR ENERGY LABORATORY CO., LTD., Atsugi-shi (JP)

(21) Appl. No.: 11/671,742

(22) Filed: Feb. 6, 2007

(30) Foreign Application Priority Data
Feb. 10, 2006 (JP) 2006-034452

(51) Int. Cl. H01L 21/00

(52) U.S. Cl. 438/22

(57) ABSTRACT

A highly functional and reliable display device with lower power consumption and higher light-emitting efficiency is provided. A light-emitting material is irradiated with light; the light-emitting material irradiated with light is dispersed in a solution containing a binder, and a solution containing the light-emitting material irradiated with light and the binder is formed; a first electrode layer is formed; the solution is applied on the first electrode layer, and a light-emitting layer containing the light-emitting material irradiated with light and the binder is formed; and a second electrode layer is formed over the light-emitting layer, and a light-emitting element is manufactured. An insulating layer may be provided between the first electrode layer and the light-emitting layer or between the second electrode layer and the light-emitting layer.

### BACKGROUND OF THE INVENTION

1. Field of the Invention

The present invention relates to a manufacturing method of a display device.

2. Description of the Related Art

In recent years, a liquid crystal display device and an electroluminescence display device, in which thin film transistors (hereinafter also referred to as TFTs) are integrated over a glass substrate, have been developed. In each of these display devices, a thin film transistor is formed over a glass substrate by using a technique for forming a thin film, and a liquid crystal element or a light-emitting element (an electroluminescence element, hereinafter also referred to as an EL element) is formed as a display element over various circuits composed of the thin film transistors so that the device functions as a display device.

Light-emitting elements utilizing electroluminescence are classified according to whether a light-emitting material is an organic compound or an inorganic compound, and generally, the former is referred to as an organic EL element and the latter is referred to as an inorganic EL element.

Inorganic EL elements are classified into a dispersion-type inorganic EL element and a thin film inorganic EL element depending on its element structure. The dispersion-type inorganic EL element has a light-emitting layer in which particles of a light-emitting material are dispersed in a binder, which can be formed by a simple method and has been widely researched (see Patent Document 1: Japanese Published Patent Application No. 2005-132947).

### SUMMARY OF THE INVENTION

However, the inorganic EL element has problems such as high drive voltage, low luminance, and low light-emitting efficiency. Therefore, further improvement in luminance and light-emitting efficiency is desired.

In view of the above problems, it is an object of the present invention to provide a highly functional and reliable display device with low power consumption and high light-emitting efficiency. In addition, it is another object to provide a manufacturing technique of a display device, which is simple, highly productive, and can also be used for a large substrate.

In addition, a display device can be manufactured by using the present invention. Display devices which can use the present invention include a light-emitting display device in which a thin film transistor (hereinafter also referred to as a TFT) is connected to a light-emitting element in which a layer exhibiting light-emission called electroluminescence or a layer containing a mixture of an organic material and an inorganic material is interposed between electrodes, and the like. EL elements include an element which at least contains a material, from which electroluminescence can be obtained, and which emits light by applied current.

Inorganic EL elements are classified into a dispersion-type inorganic EL element and a thin film inorganic EL element depending on its element structure. They are different in that the former has a light-emitting layer in which particles of a light-emitting material are dispersed in a binder, and the latter has a light-emitting layer formed by using a thin film of a fluorescent material. However, mechanisms thereof are the same, and light can be emitted due to collision excitation of a host material or the emission center caused by electrons accelerated by a high electric field.

In the present invention, a light-emitting material is irradiated with a laser beam or light emitted from a lamp light source, whereby the light-emitting material is modified and its crystallinity is improved. The modified light-emitting material is dispersed in a binder to form a light-emitting layer.

A method for manufacturing a display device according to the present invention includes the steps of: irradiating a light-emitting material with light; dispersing the light-emitting material irradiated with light in a solution containing a binder and forming a solution containing the light-emitting material irradiated with light and the binder; forming a first electrode layer; disposing the solution on the first electrode layer and forming a light-emitting layer containing the light-emitting material irradiated with light and the binder; and forming a second electrode layer over the light-emitting layer and manufacturing a light-emitting element.

Another method for manufacturing a display device according to the present invention includes the steps of: processing a light-emitting material into a particle state; irradiating the light-emitting material in a particle state with a laser beam; dispersing the light-emitting material in a particle state irradiated with the laser beam in a solution containing a binder and forming a solution containing the light-emitting material in a particle state irradiated with the laser beam and the binder; forming a first electrode layer; disposing the solution on the first electrode layer and forming a light-emitting layer containing the light-emitting material in a particle state irradiated with the laser beam and the binder; and forming a second electrode layer over the light-emitting layer and manufacturing a light-emitting element.

Another method for manufacturing a display device according to the present invention includes the steps of: irradiating a light-emitting material with a laser beam; dispersing the light-emitting material irradiated with the laser beam in a solution containing a binder and forming a solution containing the light-emitting material irradiated with the laser beam and the binder; forming a first electrode layer; disposing the solution on the first electrode layer, performing baking, and forming a light-emitting layer containing the light-emitting material irradiated with the laser beam and the binder; and forming a second electrode layer over the light-emitting layer and manufacturing a light-emitting element.

Another method for manufacturing a display device according to the present invention includes the steps of: processing a light-emitting material into a particle state; irradiating the light-emitting material in a particle state with a laser beam; dispersing the light-emitting material in a particle state irradiated with the laser beam in a solution containing a binder and forming a solution containing the light-emitting material in a particle state irradiated with the laser beam and the binder; forming a first electrode layer; disposing the solution on the first electrode layer, performing baking, and forming a light-emitting layer containing the light-emitting material in a particle state irradiated with the laser beam and the binder; and forming a second electrode layer over the light-emitting layer and manufacturing a light-emitting element.

Light with which the light-emitting material is irradiated may be a laser beam or light emitted from a lamp light source.

By light irradiation to the light-emitting material, energy is given to the light-emitting material, whereby defects or distortion can be relieved, and crystallinity can be controlled in the light-emitting material.

In the present invention, by light irradiation to a light-emitting material, defects can be reduced and distortion can be relieved in the light-emitting material, whereby crystallinity of the light-emitting material is improved. In addition, crystallinity of the light-emitting material can be controlled. Accordingly, in a light-emitting element using such a light-emitting material with favorable crystallinity, low voltage driving, high luminance, and high light-emitting efficiency can be obtained.

Therefore, a display device provided with a light-emitting element using the present invention can be a display device with low power consumption, high performance, and high reliability.

### BRIEF DESCRIPTION OF THE DRAWINGS

In the accompanying drawings:

FIGS. 1A to 1D are views each explaining a manufacturing method of a light-emitting element of the present invention;

FIGS. 2A to 2C are views each explaining a light-emitting element of the present invention;

FIGS. 3A and 3B are views each explaining a light-emitting element of the present invention;

FIGS. 4A to 4C are views each explaining a display device of the present invention;

FIGS. 5A and 5B are views each explaining a display device of the present invention;

FIGS. 6A and 6B are views each explaining a display device of the present invention;

FIGS. 7A and 7B are views each explaining a display device of the present invention;

FIG. 8 is a view explaining a display device of the present invention;

FIG. 9 is a view explaining a display device of the present invention;

FIG. 10 is a view explaining a display device of the present invention;

FIG. 11 is a view explaining a display device of the present invention;

FIGS. 12A and 12B are views each showing an electronic device to which the present invention is applied;

FIGS. 13A and 13B are a view and a diagram each showing an electronic device to which the present invention is applied;

FIG. 14 is a view showing an electronic device to which the present invention is applied;

FIGS. 15A to 15E are views each showing an electronic device to which the present invention is applied;

FIGS. 16A to 16C are top views of a display device of the present invention;

FIGS. 17A and 17B are top views of a display device of the present invention;

FIG. 18 is a diagram explaining an electronic device to which the present invention is applied; and

FIG. 19 is a view explaining a display device of the present invention.

### DESCRIPTION OF THE INVENTION

Embodiment modes of the present invention will be explained in detail with reference to the accompanying drawings. It is to be noted that the present invention is not limited to the following description, and it is easily understood by those skilled in the art that modes and details thereof can be modified in various ways without departing from the spirit and the scope of the present invention. Therefore, the present invention should not be interpreted as being limited to the following description of the embodiment modes. It is to be noted that, in structures of the present invention explained below, reference numerals indicating the same portions or portions having the similar functions are used in common in different drawings, and repeated explanation thereof will be omitted.

### Embodiment Mode 1

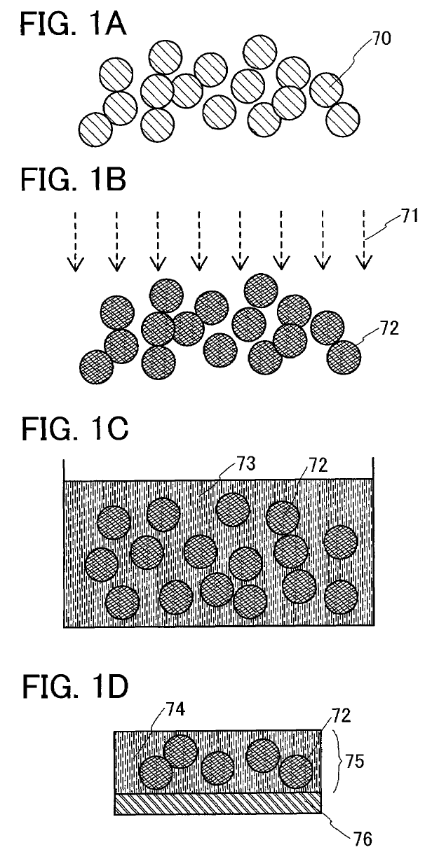

A manufacturing method of a light-emitting element in this embodiment mode will be explained in detail with reference to FIGS. 1A to 1D.

A light-emitting material which can be used in the present invention contains a host material and an impurity element which serves as the emission center. Luminescence of various colors can be obtained through the use of various impurity elements. As a manufacturing method of a light-emitting material, various methods such as a solid-phase method and a liquid-phase method (a coprecipitation method) can be used. A liquid-phase method such as a spray pyrolysis method, a double decomposition method, a method by precursor pyrolysis, a reverse micelle method, a method in which the above method and high-temperature baking are combined, or a freeze-drying method can be used.

In the solid-phase method, a host material and an impurity element are weighed, mixed in a mortar, and reacted with each other by heating and baking by an electric furnace so that the impurity element is made to be contained in the host material. Baking temperatures are preferably 700 to 1500° C. This is because solid-phase reaction does not progress at a temperature that is too low and the host material is decomposed at a temperature that is too high. Baking may be performed to the host material and the impurity element in a powder state; however, it is preferable to perform baking in a pellet state. This method requires baking at a comparatively high temperature but is simple; thus, this method has high productivity and is suitable for mass production.

In the liquid-phase method (coprecipitation method), a host material and an impurity element are reacted with each other in a solution and dried, and thereafter, they are baked. In this method, particles of the light-emitting material are uniformly dispersed, the particles each have a small diameter, and reaction can progress even at a low baking temperature.

As a host material which can be used in the present invention, sulfide, oxide, or nitride can be used. As the sulfide, for example, zinc sulfide (ZnS), cadmium sulfide (CdS), calcium sulfide (CaS), yttrium sulfide (Y₂S₃), gallium sulfide (Ga₂S₃), strontium sulfide (SrS), barium sulfide (BaS), or the like can be used. As the oxide, for example, zinc oxide (ZnO), yttrium oxide (Y₂O₃), or the like can be used. Further, as the nitride, for example, aluminum nitride (AlN), gallium nitride (GaN), indium nitride (InN), or the like can be used. In addition, zinc selenide (ZnSe), zinc telluride (ZnTe), or the like can also be used. A ternary mixed crystal such as calcium-gallium sulfide (CaGa₂S₄), strontium-gallium sulfide (SrGa₂S₄), or barium-gallium sulfide (BaGa₂S₄) may also be used.

In the present invention, a light-emitting material contains at least two kinds of impurity element. As a first impurity element, for example, copper (Cu), silver (Ag), gold (Au), platinum (Pt), silicon (Si), or the like can be used. As a second impurity element, for example, fluorine (F), chlorine (Cl), bromine (Br), iodine (I), boron (B), aluminum (Al), gallium (Ga), indium (In), thallium (Tl), or the like can be used.

A light-emitting material containing the above material as a host material and only the above first and second impurity elements as the emission center can be used. Such a light-emitting material exhibits light-emission due to donor-acceptor recombination.

As an impurity element in a light-emitting material, the first impurity element and a third impurity element may be used so that the light-emitting material contains two kinds of impurity element. As the third impurity element, for example, lithium (Li), sodium (Na), pottaisum (K), rubidium (Rb), cesium (Cs), nitrogen (N), phosphorus (P), arsenic (As), antimony (Sb), bismuth (Bi), or the like can be used.

As an impurity element in the light-emitting material, further, the third impurity element may be used in addition to the first impurity element and the second impurity element so that the light-emitting material contains three kinds of impurity element. The concentration of these impurity elements may be 0.01 to 10 mol % with respect to the host material, preferably, in the range of 0.1 to 5 mol %.

As an impurity element in the case where solid-phase reaction is utilized, a compound containing the first impurity element and the second impurity element or a compound containing the second impurity element and the third impurity element may be used. In this case, the impurity elements can be easily dispersed, and solid-phase reaction can progress easily, whereby a uniform light-emitting material can be obtained. Further, since an extra impurity element is not mixed, a light-emitting material with high purity can be obtained. As the compound containing the first impurity element and the second impurity element, for example, copper fluoride (CuF₂), copper chloride (CuCl), copper iodide (CuI), copper bromide (CuBr), copper nitride (Cu₃N), copper phosphide (Cu₃P), silver fluoride (AgF), silver chloride (AgCl), silver iodide (AgI), silver bromide (AgBr), gold chloride (AuCl₃), gold bromide (AuBr₃), platinum chloride (PtCl₂), or the like can be used. In addition, as the compound containing the second impurity element and the third impurity element, for example, alkali halide such as lithium fluoride (LiF), lithium chloride (LiCl), lithium iodide (LiI), lithium bromide (LiBr), or sodium chloride (NaCl), boron nitride (BN), aluminum nitride (AlN), aluminium antimonide (AlSb), gallium phosphide (GaP), gallium arsenide (GaAs), indium phosphide (InP), indium arsenide (InAs), indium antimonide (InSb), or the like can be used.

In the light-emitting material obtained as described above, light-emission due to recombination of a donor-acceptor pair can be obtained, and the light-emitting material has high conductivity. A light-emitting layer using the light-emitting material containing three kinds of impurity element can emit light without requiring hot electrons accelerated by a high electric filed. In other words, it is not necessary to apply high voltage to the light-emitting element; thus, a light-emitting element which can be driven with low drive voltage can be obtained. In addition, since the light-emitting element can emit light with low drive voltage, a light-emitting element with reduced power consumption can be obtained.

Further, in a light-emitting material which does not utilize donor-acceptor recombination, for example, the above material can be used as a host material. In addition, as the emission center, manganese (Mn), copper (Cu), samarium (Sm), terbium (Tb), erbium (Er), thulium (Tm), europium (Eu), cerium (Ce), praseodymium (Pr), or the like can be used. Light-emission due to such a light-emitting material utilizes an inner-shell electronic transition of a metal ion. It is to be noted that not only metal is used as such a light-emitting material, but also a halogen element such as fluorine (F) or chlorine (Cl) may be added for charge compensation.

The light-emitting material manufactured by the above method is processed into particles. The light-emitting material may be processed into particles by being crushed in a mortar or the like, or through the use of a device such as a mill. When a particle having a sufficiently desired size can be obtained by a manufacturing method of the light-emitting material, further processing may not be performed. The particle diameter may be greater than or equal to 0.1 μm and less than or equal to 50 μm (much preferably, less than or equal to 10 μm). The shape of the light-emitting material may be any shape such as a particle shape, a columnar shape, a needle shape, or a planar shape. Alternatively, particles of a plurality of light-emitting materials may be cohered to be aggregation as a simple material.

FIG. 1A shows a light-emitting material 70 in a particle state. In the present invention, the light-emitting material 70 is irradiated with light 71. After the light-emitting material 70 is irradiated with the light 71, the light-emitting material is modified to become a light-emitting material 72 as shown in FIG. 1B. As the light 71, for example, light of the wavelength of 100 to 300 nm may be used. By light irradiation, dangling bonds of atoms in the light-emitting material are bonded to each other, whereby defects are reduced. With reduced defects, distortion is relieved and crystallinity is improved. In addition, by light irradiation, crystallinity of the light-emitting material can also be controlled to be a desired crystal system such as a hexagonal system or a cubic system. Crystallinity can be more effectively controlled by light irradiation and addition of an impurity element which has an effect of promoting the light-emitting material to have a particular crystal system (for example, gallium phosphide (GaP), gallium arsenide (GaAs), gallium antimonide (GaSb), indium phosphide (InP), indium arsenide (InAs), indium antimonide (InSb), silicon (Si), germanium (Ge), gallium nitride (GaN), indium nitride (InN), aluminum phosphide (AlP), aluminium antimonide (AlSb), aluminum nitride (AlN), or the like). Therefore, crystallinity is improved; thus, light-emitting efficiency of the light-emitting element can also be improved.

Light which is used is not particularly limited, and any of infrared light, visible light, and ultraviolet light, or combination thereof can be used. For example, light emitted from an ultraviolet lamp, a black light, a halogen lamp, a metal halide lamp, a xenon arc lamp, a carbon arc lamp, a high pressure sodium lamp, or a high pressure mercury lamp may be used. In such a case, light from a lamp light source may be emitted for a required period or emitted a plurality of times for irradiation.

In addition, a laser beam may also be used as the light. As a laser oscillator, a laser oscillator capable of emitting ultraviolet light, visible light, or infrared light can be used. As the laser oscillator, an excimer laser such as a KrF excimer laser, an ArF excimer laser, a XeCl excimer laser, or a Xe excimer laser; a gas laser such as a He laser, a He—Cd laser, an Ar laser, a He—Ne laser, or a HF laser; a solid-state laser using a crystal such as YAG, GdVO₄, YVO₄, YLF, or YAlO₃ doped with Cr, Nd, Er, Ho, Ce, Co, Ti, or Tm; or a semiconductor laser such as a GaN laser, a GaAs laser, a GaAlAs laser, or an InGaAsP laser can be used. As for the solid-state laser, it is preferable to use the first to fifth harmonics of the fundamental wave. In order to adjust the shape or path of a laser beam emitted from the laser oscillator, an optical system including a shutter, a reflector such as a mirror or a half mirror, a cylindrical lens, a convex lens, or the like may be provided.

It is to be noted that laser beam irradiation may be selectively performed or may be performed by scanning the beam in the X— and Y-axis directions. In this case, a polygon mirror or a galvanometer mirror is preferably used for the optical system.

In addition, a combination of light emitted from a lamp light source and a laser beam can also be used as the light. A region where exposure is performed for the relatively wide range may be irradiated with the use of a lamp, and only a region where minute exposure is performed may be irradiated with a laser beam. By light irradiation treatment performed in such a manner, throughput can be improved.

In addition, light irradiation may be performed concurrently with other heat treatment. For example, while heating a substrate provided with a light-emitting material (preferably to 50 to 500° C.), light irradiation is performed from the upper side (the lower side or both sides) to modify the light-emitting material.

In the present invention, since the light-emitting material processed in a particle state is irradiated with light, much larger area can be irradiated with light. Therefore, the light-emitting material can be sufficiently modified by light irradiation in which the particles are moved by stirring or the like so that the entire surface area of the particle is irradiated with light.

As shown in FIG. 1C, the modified light-emitting material 72 is dispersed in a solution 73 containing a binder. The solution 73 containing a binder may be stirred so that the light-emitting material is uniformly dispersed. The viscosity of the solution may be appropriately set, while keeping fluidity, so that a desired film thickness for a light-emitting layer can be obtained. The binder is a substance used for fixing the particles of the light-emitting material in a dispersed state and keeping a shape as a light-emitting layer.

The solution 73 containing a binder, in which the light-emitting material 72 is dispersed, is applied on an electrode layer 76 by a wet process such as a printing method and dried to be solidified, whereby a light-emitting layer 75 is formed (see FIG. 1D). A solvent is evaporated and removed so that the light-emitting layer 75 contains the binder 74 and the light-emitting material 72. The light-emitting material 72 is uniformly dispersed and solidified in the light-emitting layer 75 by the binder 74.

As a method for forming the light-emitting layer 75, a droplet-discharging method capable of selectively forming a light-emitting layer, a printing method (such as screen printing or offset printing), a coating method such as a spin coating method, a dipping method, a dispenser method, or the like can be used. A film thickness is not particularly limited, but is preferably in the range of 10 to 1000 nm. Further, in the light-emitting layer containing the light-emitting material and the binder, the ratio of the light-emitting material is preferably greater than or equal to 50 wt % and less than or equal to 80 wt %.

As a binder that can be used in the present invention, an insulating material can be used. More specifically, an organic material, an inorganic material, or a mixed material of an organic material and an inorganic material can be used. As an organic insulating material, the following resin material can be used: a polymer having a comparatively high dielectric constant such as a cyanoethyl cellulose based resin, polyethylene, polypropylene, a polystyrene based resin, a silicone resin, an epoxy resin, vinylidene fluoride, or the like. In addition, a heat-resistant high-molecular material such as aromatic polyamide or polybenzimidazole, or a siloxane resin may also be used. The siloxane resin is a resin including a Si—O—Si bond. Siloxane has a skeleton structure formed of a bond of silicon (Si) and oxygen (O). As a substituent, an organic group containing at least hydrogen (for example, an alkyl group or aromatic hydrocarbon) is used. Alternatively, a fluoro group may be used as a substituent. In addition, as a substituent, both a fluoro group and an organic group containing at least hydrogen may also be used. Further, the following resin material may also be used: a vinyl resin such as polyvinyl alcohol or polyvinylbutyral, a phenol resin, a novolac resin, an acrylic resin, a melamine resin, an urethane resin, an oxazole resin (polybenzoxazole), or the like. In addition, a photo-curable resin or the like can be used. Fine particles having a high dielectric constant such as BaTiO₃ or SrTiO₃ can also be mixed to these resins moderately, whereby a dielectric constant is adjusted.

As an inorganic insulating material contained in the binder, a material of silicon oxide, silicon nitride, silicon oxynitride, silicon nitride oxide, aluminum nitride (AlN), aluminum oxynitride (AlON), aluminum nitride oxide (AlNO), aluminum oxide, titanium oxide (TiO₂), BaTiO₃, SrTiO₃, PbTiO₃, KNbO₃, PbNbO₃, Ta₂O₃, BaTa₂O₆, LiTaO₃, Y₂O₃, ZrO₂, ZnS, or other substances containing an inorganic insulating material can be given. When an inorganic material having a high dielectric constant is made to be contained in an organic material (by addition or the like), a dielectric constant of the light-emitting layer containing the light-emitting material and the binder can be more efficiently controlled and can be much higher.

As the solvent for the solution containing a binder that can be used in the present invention, a solvent capable of forming a solution having such viscosity, that can dissolve a binder material and which is suitable for a method for forming a light-emitting layer (various wet processes) and a desired film thickness, may be appropriately selected. An organic solvent or the like can also be used, and when, for example, a siloxane resin is used as a binder, propylene glycol monomethyl ether, propylene glycol monomethyl ether acetate (also referred to as PGMEA), 37-methoxy-3-methyl-1-butanol (also referred to as MMB), or the like can be used.

Thereafter, an electrode layer is formed over the light-emitting layer, whereby a light-emitting element in which a light-emitting layer is interposed between a pair of electrode layers is completed.

The electrode layers interposing the light-emitting layer (a first electrode layer and a second electrode layer) can be formed by using metal, alloy, a conductive compound, a mixture thereof, or the like. Specifically, for example, indium oxide-tin oxide (ITO: Indium Tin Oxide), indium oxide-tin oxide containing silicon or silicon oxide, indium oxide-zinc oxide (IZO: Indium Zinc Oxide), tungsten oxide-indium oxide containing zinc oxide (IWZO), or the like can be used. These conductive metal oxide films are generally formed by sputtering. For example, indium oxide-zinc oxide (IZO) can be formed by sputtering using a target in which 1 to 20 wt % of zinc oxide is added to indium oxide. In addition, tungsten oxide-indium oxide containing zinc oxide (IWZO) can be formed by sputtering using a target in which 0.5 to 5 wt % of tungsten oxide and 0.1 to 1 wt % of zinc oxide are mixed with indium oxide. Besides, aluminum (Al), silver (Ag), gold (Au), platinum (Pt), nickel (Ni), tungsten (W), chromium (Cr), molybdenum (Mo), iron (Fe), cobalt (Co), copper (Cu), palladium (Pd), metal nitride (such as titanium nitride: TiN), or the like can also be used. In the case of a light-transmitting electrode layer, even a material with low transmittance of visible light can be used as a light-transmitting electrode by being formed to be 1 to 50 nm thick, preferably, 5 to 20 nm thick. It is to be noted that vacuum evaporation, CVD, and a sol-gel method can also be used in addition to sputtering to manufacture the electrode. Since light-emission is extracted to an external portion through the electrode layer, at least one of a pair of the electrode layers (the first electrode layer and the second electrode layer) or both of them are required to be formed by using a light-transmitting material.

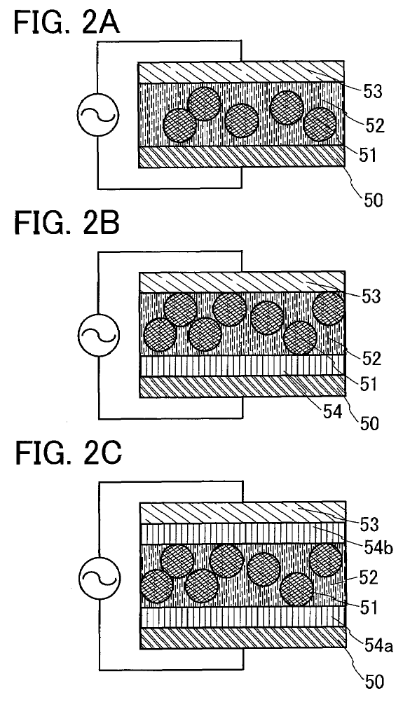

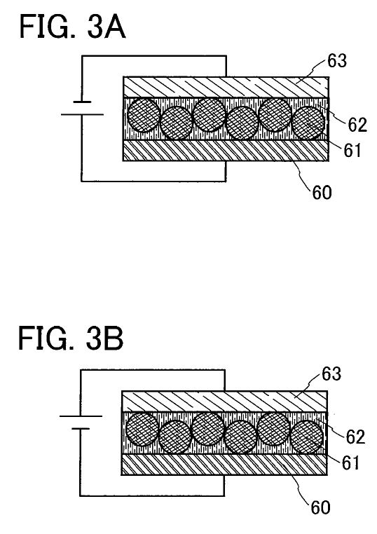

FIGS. 2A to 2C, and 3A and 3B each show a light-emitting element which can be manufactured in this embodiment mode.

A light-emitting element in FIG. 2A has a stacked structure of a first electrode layer 50, a light-emitting layer 52, and a second electrode layer 53, and contains a light-emitting material 51 held by a binder in the light-emitting layer 52. It is to be noted that FIGS. 2A to 2C each show an AC-driving light-emitting element. In FIG. 2A, a mixed layer of an inorganic material and an organic material is preferably used for the binder in the light-emitting layer 52, whereby a high dielectric constant is obtained. Accordingly, the large amount of electric charge can be induced in the light-emitting material. In addition, the light-emitting material 51 is preferably dispersed so that the first electrode layer 50 and the second electrode layer 53 are not connected indirectly by the light-emitting material 51. In the light-emitting elements shown in this embodiment mode, light is emitted by voltage applied between the first electrode layer 50 and the second electrode layer 53, and the light-emitting element can operate by either DC-driving or AC-driving.

Each of light-emitting elements shown in FIGS. 2B and 2C has a structure in which an insulating layer is provided between the electrode layer and the light-emitting layer in the light-emitting element of FIG. 2A. The light-emitting element shown in FIG. 2B includes an insulating layer 54 between a first electrode layer 50 and a light-emitting layer 52, and the light-emitting element shown in FIG. 2C includes an insulating layer 54a between a first electrode layer 50 and a light-emitting layer 52, and an insulating layer 54b between a second electrode layer 53 and the light-emitting layer 52. In such a manner, the insulating layer may be provided between one of the pair of the electrode layers and the light-emitting layer or between both the electrode layers and the light-emitting layer. In addition, the insulating layer may be a single layer or a stacked layer including a plurality of layers.

In addition, in FIG. 2B, although the insulating layer 54 is provided so as to be in contact with the first electrode layer 50, the order of the insulating layer and the light-emitting layer may be inverted so that the insulating layer 54 is provided so as to be in contact with the second electrode layer 53.

The insulating layers 54a and 54b are not particularly limited; however, they have preferably a high insulating property, dense film quality, and further, a high dielectric constant. For example, silicon oxide (SiO₂), yttrium oxide (Y₂O₃), titanium oxide (TiO₂), aluminum oxide (Al₂O₃), hafnium oxide (HfO₂), tantalum oxide (Ta₂O₅), barium titanate (BaTiO₃), strontium titanate (SrTiO₃), lead titanate (PbTiO₃), silicon nitride (Si₃N₄), zirconium oxide (ZrO₂), or the like, a mixed film thereof, or a stacked film containing two or more kinds of the above material can be used. These insulating films can be formed by sputtering, evaporation, CVD, or the like. In addition, particles of these insulating materials may be dispersed in a binder to form the insulating layers 54a and 54b. The binder material may be formed by using the same material and the same method as those of the binder contained in the light-emitting layer. The film thickness is not particularly limited but preferably in the range of 10 to 1000 nm.

Although not shown in the drawings, a buffer layer may be provided between the light-emitting layer and the insulating layer or between the light-emitting layer and the electrode. This buffer layer has a function of making carrier-injection easy and preventing the both layers from mixing. The buffer layer is not particularly limited, and for example, ZnS, ZnSe, ZnTe, CdS, SrS, BaS, or the like which is a host material of the light-emitting layer, CuS or Cu₂S, or LiF, CaF₂, BaF₂, MgF₂ or the like which is a alkali halide can be used.

Each of FIGS. 3A and 3B shows an example in which the light-emitting element is driven by direct current. Each of the light-emitting elements in this embodiment mode shown in FIGS. 3A and 3B has a stacked structure of a first electrode layer 60, a light-emitting layer 62, and a second electrode layer 63, and contains a light-emitting material 61 held by a binder in the light-emitting layer 62. FIG. 3A is an example in which the first electrode layer 60 and the second electrode layer 63 are electrically connected to each other so as to function as an anode and a cathode, respectively. FIG. 3B is an example in which the first electrode layer 60 and the second electrode layer 63 are electrically connected to each other so as to function as a cathode and an anode, respectively.

In the case of DC driving, as shown in FIGS. 3A and 3B, the film thickness of the light-emitting layer 62 is made thin, the light-emitting material 61 is fixed by the binder so as to be in contact with the first electrode layer 60 and the second electrode layer 63, and the first electrode layer 60 and the second electrode layer 63 are connected to each other with the light-emitting material 61 interposed therebetween. Therefore, carriers are easily injected to the light-emitting material, which is preferable.

In each of the light-emitting elements of FIGS. 2A to 2C and 3A and 3B, a substrate as a supporting body and a sealing substrate facing the display device are not illustrated. The substrate as a supporting body and the sealing substrate may be provided on either the first electrode layer side or the second electrode layer side without any limitation.

By light irradiation to the light-emitting material used in the present invention, dangling bonds of atoms in the light-emitting material are bonded to each other, whereby defects are reduced and crystallinity is improved. In addition, through the use of a light-emitting element using such a light-emitting material with favorable crystallinity, low-voltage driving, high luminance, and high light-emitting efficiency can be obtained.

Accordingly, by using the present invention, a display device with low power consumption, high performance, and high reliability can be manufactured at low cost with high productivity.

### Embodiment Mode 2

This embodiment mode will explain one structural example of a display device including the light-emitting element of the present invention with reference to the drawings. More specifically, the case where a structure of a display device is a passive matrix type will be shown.

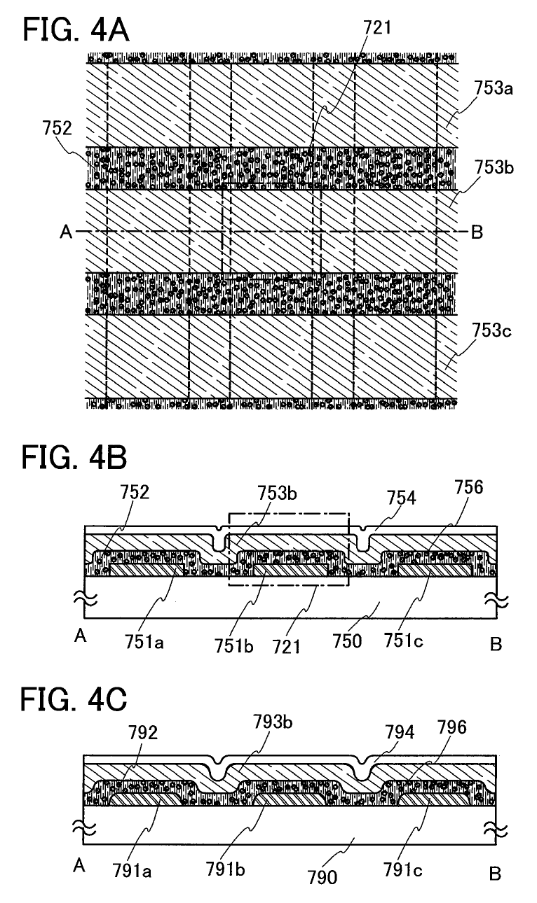

The display device includes first electrode layers 751a, 751b, and 751c extending in a first direction; a light-emitting layer 752 provided to cover the first electrode layers 751a, 751b, and 751c; and second electrode layers 753a, 753b, and 753c extending in a second direction perpendicular to the first direction (see FIG. 4A). The light-emitting layer 752 is provided between the first electrode layers 751a, 751b, and 751c and the second electrode layers 753a, 753b, and 753c. In addition, an insulating layer 754 functioning as a protective film is provided so as to cover the second electrode layers 753a, 753b, and 753c (see FIG. 4B). When an influence of an electric field in a lateral direction is concerned between adjacent light-emitting elements, the light-emitting layer 752 containing a light-emitting material 756 provided in each light-emitting element 721 may be separated.

FIG. 4C is a deformed example of FIG. 4B. Over a substrate 790, first electrode layers 791a, 791b, and 791c, a light-emitting layer 792 containing a light-emitting material 796, a second electrode layer 793b, and an insulating layer 794 which is a protective layer are provided. The first electrode layer may have a tapered shape like the first electrode layers 791a, 791b, and 791c in FIG. 4C, or a shape in which radius of curvature changes continuously. The shape like the first electrode layers 791a, 791b, and 791c can be formed with the use of a droplet-discharging method or the like. With such a curved surface having a curvature, coverage of the stacked insulating layer or conductive layer is favorable.

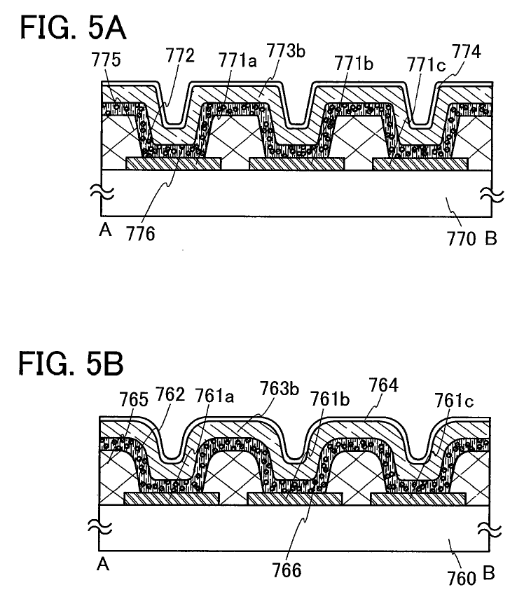

In addition, a partition wall (insulating layer) may be formed to cover the edge of the first electrode layer. The partition wall (insulating layer) serves as a wall separating a light-emitting element and another light-emitting element. FIGS. 5A and 5B each show a structure in which the edge of the first electrode layer is covered with the partition wall (insulating layer).

In an example of a light-emitting element shown in FIG. 5A, a partition wall (insulating layer) 775 is formed into a tapered shape to cover edges of first electrode layers 771a, 771b, and 771c. The partition wall (insulating layer) 775 is formed over the first electrode layers 771a, 771b, and 771c provided over a substrate 770. Thereafter, a light-emitting layer 772 containing a light-emitting material 776, a second electrode layer 773b, and an insulating layer 774 are formed.

An example of a light-emitting element shown in FIG. 5B has a shape in which a partition wall (insulating layer) 765 has a curvature, and radius of the curvature changes continuously. The partition wall (insulating layer) 765 is formed over first electrode layers 761a, 761b, and 761c provided over a substrate 760. Thereafter, a light-emitting layer 762 containing a light-emitting material 766, a second electrode layer 763b, and an insulating layer 764 are formed.

The light-emitting layers 752, 762, 772, and 792 manufactured by using the present invention each contain a light-emitting material fixed by a binder. In this embodiment mode, the light-emitting material in a particle state is irradiated with light, the light-emitting material is modified, and crystallinity of the light-emitting material is improved. By light irradiation, dangling bonds of atoms in the light-emitting material are bonded to each other, whereby defects are reduced and distortion is relieved in the light-emitting material. Therefore, a light-emitting material with favorable crystallinity can be used, whereby luminance and light-emitting efficiency of the light-emitting element can be improved and power consumption can also be reduced. Therefore, a display device with high performance and high reliability can be manufactured.

As the substrates 750, 760, 770, and 790, a quartz substrate, a silicon substrate, a metal substrate, a stainless-steel substrate, or the like, in addition to a glass substrate and a flexible substrate, can be used. The flexible substrate is a substrate that can be bent, such as a plastic substrate formed using polycarbonate, polyarylate, polyether sulfone, or the like. In addition, a film (formed using polypropylene, polyester, vinyl, polyvinyl fluoride, vinyl chloride, or the like), paper of a fibrous material, an inorganic evaporated film, or the like can be used. Alternatively, the light-emitting element can be provided over a field effect transistor (FET) formed over a semiconductor substrate such as a Si substrate, or over a thin film transistor (TFT) formed over a substrate such as a glass substrate.

The first electrode layer, the second electrode layer, the light-emitting material, and the light-emitting layer shown in this embodiment mode can be formed by using any of the materials and the methods described in Embodiment Mode 1.

As the partition walls (insulating layers) 765 and 775, silicon oxide, silicon nitride, silicon oxynitride, aluminum oxide, aluminum nitride, aluminum oxynitride, or other inorganic insulating materials; acrylic acid, methacrylic acid, or a derivative thereof; a heat-resistant high molecular material such as polyimide, aromatic polyamide, or polybenzimidazole; or a siloxane resin may be used. Alternatively, the following resin material can be used: a vinyl resin such as polyvinyl alcohol or polyvinylbutyral, an epoxy resin, a phenol resin, a novolac resin, an acrylic resin, a melamine resin, a urethane resin, or the like. Further, an organic material such as benzocyclobutene, parylene, fluorinated arylene ether, or polyimide; a composition material containing a water-soluble homopolymer and a water-soluble copolymer; or the like may be used. As a manufacturing method, a vapor phase growth method such as a plasma CVD method or a thermal CVD method, or a sputtering method can be used. A droplet-discharging method or a printing method (a method for forming a pattern, such as screen printing or offset printing) can also be used. A coating film or an SOG film obtained by a coating method or the like can also be used.

After a conductive layer, an insulating layer, or the like is formed by discharge of a composition by a droplet-discharging method, a surface thereof may be planarized by pressing with pressure to enhance planarity. As a pressing method, concavity and convexity of the surface may be reduced by scanning of a roller-shaped object on the surface, or the surface may be pressed with a flat plate-shaped object. Heating treatment may also be performed at the time of pressing. Alternatively, the concavity and convexity of the surface may be removed with an air knife after the surface is softened or melted with a solvent or the like. A CMP method may also be used for polishing the surface. This step can be employed in planarizing of a surface when concavity and convexity are generated by a droplet-discharging method.

By light irradiation to the light-emitting material used in the present invention, dangling bonds of atoms in the light-emitting material are bonded to each other, whereby defects are reduced and crystallinity is improved. Therefore, through the use of a light-emitting element using such a light-emitting material with favorable crystallinity, low-voltage driving, high luminance, and high light-emitting efficiency can be obtained.

Accordingly, by using the present invention, a display device with low power consumption, high performance, and high reliability can be manufactured at low cost with high productivity.

### Embodiment Mode 3

This embodiment mode will explain a display device having a structure which is different from that of Embodiment Mode 2. Specifically, the case where a structure of a display device is an active matrix type will be shown.

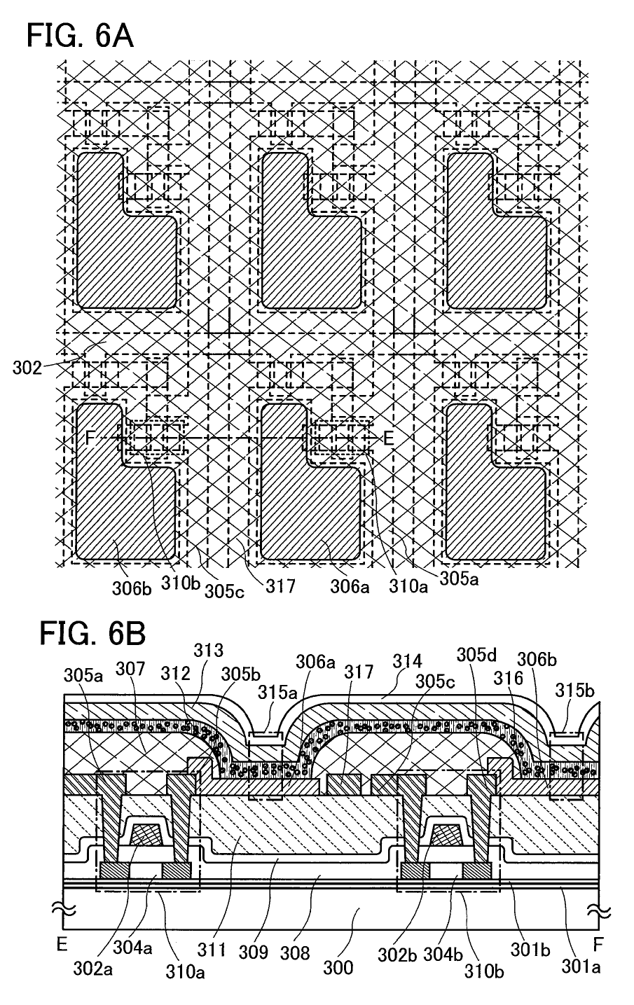

FIG. 6A shows a top view of the display device, and FIG. 6B shows a cross-sectional view taken along a line E-F in FIG. 6A. In addition, in FIG. 6A, a light-emitting layer 312 containing a light-emitting material 316, a second electrode layer 313, and an insulating layer 314 are omitted and not illustrated, but provided as shown in FIG. 6B.

A first wiring extending in a first direction and a second wiring extending in a second direction perpendicular to the first direction are provided in a matrix. The first wiring is connected to a source electrode or a drain electrode of each of transistors 310a and 310b, and the second wiring is connected to a gate electrode of each of the transistors 310a and 310b. First electrode layers 306a and 306b are each connected to the source electrode or the drain electrode of the transistors 310a and 310b, which is not connected to the first wiring. Light-emitting elements 315a and 315b are provided by a stacked structure of the first electrode layers 306a and 306b, the light-emitting layer 312 containing the light-emitting material 316, and the second electrode layer 313. A partition wall (insulating layer) 307 is provided between the adjacent light-emitting elements. Over the first electrode layer and the partition wall (insulating layer) 307, the light-emitting layer 312 containing the light-emitting material 316 and the second electrode layer 313 are stacked. An insulating layer 314 that is a protective layer is provided over the second electrode layer 313. In addition, a thin film transistor is used for each of the transistors 310a and 310b (see FIG. 6B).

The light-emitting element of FIG. 6B is provided over a substrate 300. Over the substrate 300, insulating layers 301a, 301b, 308, 309, and 311; a wiring 317; a semiconductor layer 304a, a gate electrode layer 302a, and a wiring 305a and a wiring 305b also serving as a source electrode layer or a drain electrode layer, which form the transistor 310a; and a semiconductor layer 304b, a gate electrode layer 302b, and a wiring 305c and a wiring 305d also serving as a source electrode layer or a drain electrode layer, which form the transistor 310b are provided. Over the first electrode layers 306a and 306b, and the partition wall (insulating layer) 307, the light-emitting layer 312 containing the light-emitting material 316 and the second electrode layer 313 are formed.

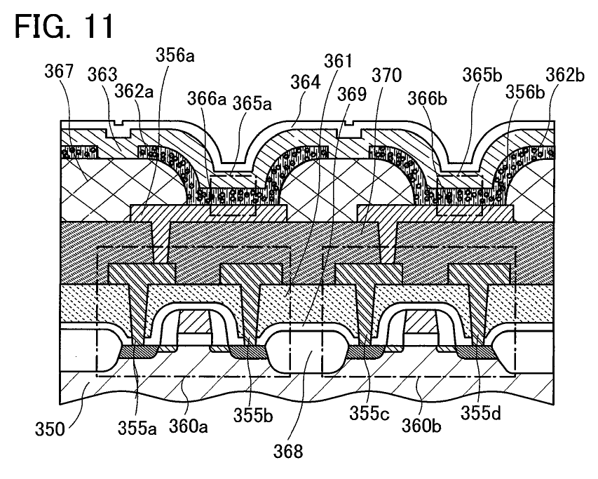

In addition, as shown in FIG. 11, light-emitting elements 365a and 365b may be connected to field effect transistors 360a and 360b, respectively, which are provided over a single crystal semiconductor substrate 350. Here, an insulating layer 370 is provided so as to cover source or drain electrode layers 355a to 355d of the field effect transistors 360a and 360b. Over the insulating layer 370, the light-emitting elements 365a and 365b are formed using first electrode layers 356a and 356b, a partition wall (insulating layer) 367, a light-emitting layer 362a containing a light-emitting material 366a, a light-emitting layer 362b containing a light-emitting material 366b, and a second electrode layer 363. A light-emitting layer may be selectively provided with the use of a mask or the like for each light-emitting element, like the light-emitting layer 362a containing the light-emitting material 366a and the light-emitting layer 362b containing the light-emitting material 366b. In addition, the display device shown in FIG. 11 also includes an element separating region 368, insulating layers 369, 361, and 364. Over the first electrode layers 356a and 356b, and the partition wall 367, the light-emitting layer 362a containing the light-emitting material 366a and the light-emitting layer 362b containing the light-emitting material 366b are formed. Further, over the light-emitting layer 362a containing the light-emitting material 366a and the light-emitting layer 362b containing the light-emitting material 366b, the second electrode layer 363 is formed.

The light-emitting layers 312, 362a, and 362b manufactured by using the present invention contain a light-emitting material fixed by a binder. In this embodiment mode, the light-emitting material in a particle state is irradiated with light, whereby the light-emitting material is modified and crystallinity of the light-emitting material is improved. By light irradiation, dangling bonds of atoms in the light-emitting material are bonded to each other, whereby defects are reduced and crystallinity is improved in the light-emitting material. Accordingly, a light-emitting material with favorable crystallinity can be used, whereby luminance and light-emitting efficiency of the light-emitting element can be improved, and power consumption can also be reduced. Therefore, a display device with high performance and high reliability can be manufactured.

When the insulating layer 370 is provided to form the light-emitting element as shown in FIG. 11, the first electrode layer can be freely arranged. In other words, although the light-emitting elements 315a and 315b are required to be provided in a region where the source electrode layer or the drain electrode layer of the transistors 310a and 310b is not provided in the structure of FIG. 6B, the light-emitting elements 315a and 315b can be formed, for example, over the transistors 310a and 310b by the above structure. Consequently, the display device can be more highly integrated.

The transistors 310a and 310b may be provided in any structure as long as they can function as a switching element. Various semiconductors such as an amorphous semiconductor, a crystalline semiconductor, a polycrystalline semiconductor, and a microcrystal semiconductor can be used as a semiconductor layer, and an organic transistor may also be formed by using an organic compound. FIG. 6A shows an example in which a planar type thin film transistor is provided over an insulating substrate; however, a transistor can also be a staggered type or a reverse staggered type.

By light irradiation to the light-emitting material used in the present invention, dangling bonds of atoms in the light-emitting material are bonded to each other, whereby defects are reduced and crystallinity is improved. Therefore, through the use of a light-emitting element using such a light-emitting material with favorable crystallinity, low-voltage driving, high luminance, and high light-emitting efficiency can be obtained.

Accordingly, by using the present invention, a display device with low power consumption, high performance, and high reliability can be manufactured at low cost with high productivity.

### Embodiment Mode 4

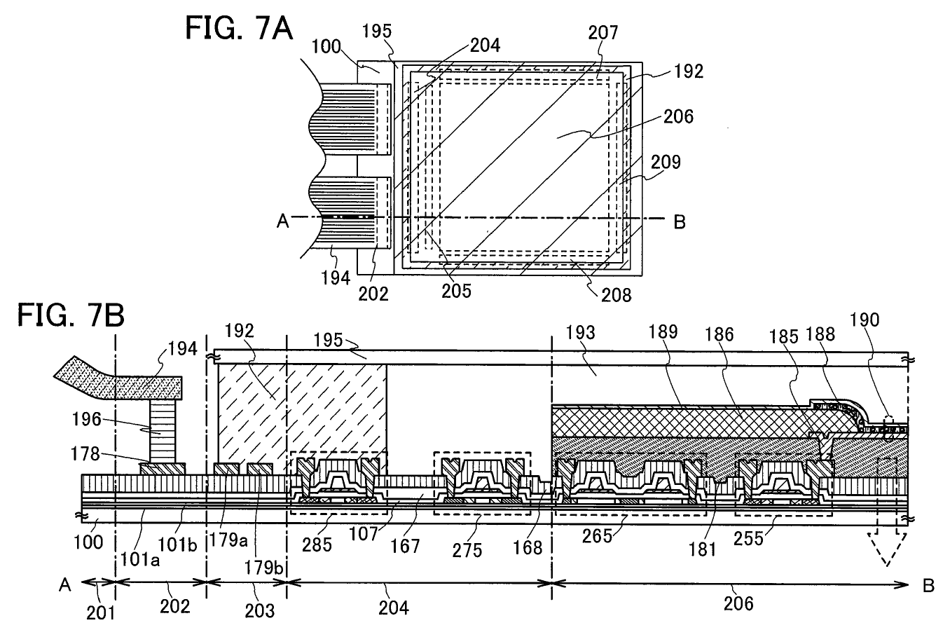

A manufacturing method of a display device in this embodiment mode will be explained in detail with reference to FIGS. 7A and 7B, 8, 16A to 16C, and 17A and 17B.

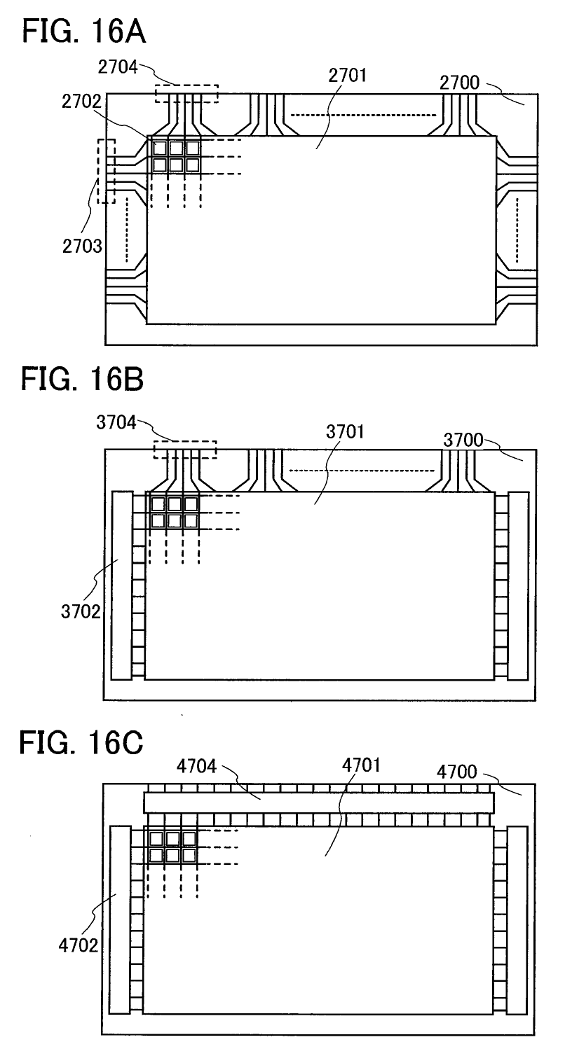

FIG. 16A is a top view showing a structure of a display panel in accordance with the present invention, which includes, over a substrate 2700 having an insulating surface, a pixel portion 2701 in which pixels 2702 are arranged in a matrix, a scanning line input terminal 2703, and a signal line input terminal 2704. The number of pixels may be set depending on various standards: 1024×768×3 (RGB) in the case of XGA and full-color display using RGB, 1600×1200×3 (RGB) in the case of UXGA and full-color display using RGB, and 1920×1080×3 (RGB) in the case of full spec high vision and full-color display using RGB.

The pixels 2702 are arranged in a matrix since a scanning line extending from the scanning line input terminal 2703 and a signal line extending from the signal line input terminal 2704 are intersected. Each of the pixels 2702 is provided with a switching element and a pixel electrode layer connected thereto. A typical example of the switching element is a TFT. A gate electrode layer side of the TFT is connected to the scanning line, and a source or drain side of the TFT is connected to the signal line; thus, each pixel can be controlled independently by a signal input from an external portion.

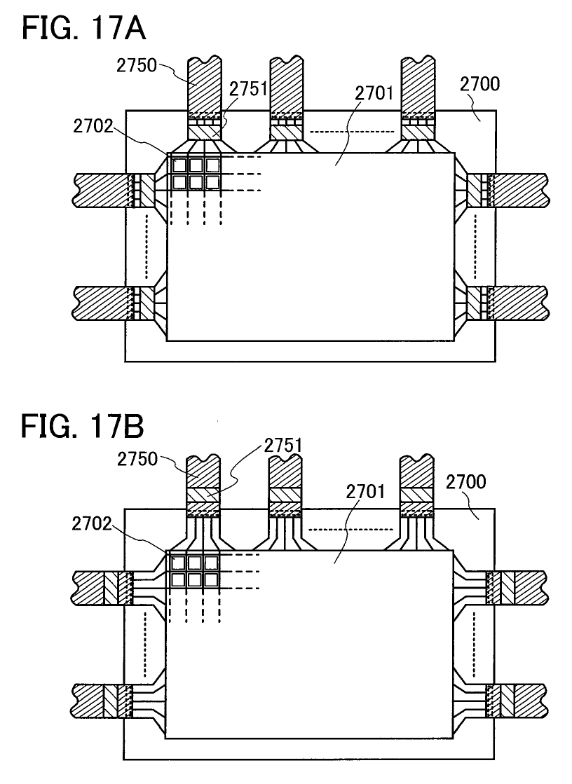

FIG. 16A shows a structure of a display panel in which a signal to be input to the scanning line and the signal line is controlled by an external driver circuit; however, a driver IC 2751 may also be mounted on the substrate 2700 by a COG (Chip On Glass) method as shown in FIG. 17A. Further, as another mode, a TAB (Tape Automated Bonding) method as shown in FIG. 17B may also be employed. A driver IC may be formed over a single crystal semiconductor substrate or a glass substrate by using a TFT. In FIGS. 17A and 17B, the driver IC 2751 is connected to an FPC (Flexible Printed Circuit) 2750.

Further, in the case where a TFT provided in a pixel is formed by using a crystalline semiconductor, a scanning line driver circuit 3702 can be formed over a substrate 3700 as shown in FIG. 16B. In FIG. 16B, a pixel portion 3701 is controlled by an external driver circuit, to which a signal line input terminal 3704 is connected, similarly to FIG. 16A. In the case where a TFT provided in a pixel is formed by using a polycrystalline (microcrystalline) semiconductor, a single crystal semiconductor, and the like with high mobility, a pixel portion 4701, a scanning line driver circuit 4702, and a signal line driver circuit 4704 can be formed to be integrated over a substrate 4700 as shown in FIG. 16C.

As shown in FIGS. 7A and 7B, over a substrate 100 having an insulating surface, a base film is formed. In this embodiment mode, a base film 101a is formed using silicon nitride oxide to be 10 to 200 nm thick (preferably, 50 to 150 nm thick), and a base film 101b is stacked thereover using silicon oxynitride to be 50 to 200 nm thick (preferably, 100 to 150 nm thick). As another material used for the base film, acrylic acid, methacrylic acid, and a derivative thereof, a heat-resistant high-molecular material such as polyimide, aromatic polyamide, or polybenzimidazole, or a siloxane resin may be used. Further, the following resin material may also be used: a vinyl resin such as polyvinyl alcohol or polyvinylbutyral, an epoxy resin, a phenol resin, a novolac resin, an acrylic resin, a melamine resin, an urethane resin, or the like. In addition, an organic material such as benzocyclobutene, parylene, fluorinated arylene ether, or polyimide; a composite material containing a water-soluble homopolymer and a water-soluble copolymer; or the like may be used. In addition, an oxazole resin can be used, and for example, photo-curable type polybenzoxazole or the like can be used.

As a method for forming the base film, a sputtering method, a PVD (Physical Vapor Deposition) method, a CVD (Chemical Vapor Deposition) method such as a low pressure CVD (LPCVD) method or a plasma CVD method, a droplet-discharging method, a printing method (a method for forming a pattern, such as screen printing or offset printing), a coating method such as a spin coating method, a dipping method, a dispenser method or the like can be used. In this embodiment mode, the base films 101a and 101b are formed by a plasma CVD method. The substrate 100 may be a glass substrate, a quartz substrate, a silicon substrate, a metal substrate, or a stainless steel substrate having a surface covered with an insulating film. Further, a plastic substrate having heat resistance which can resist a processing temperature of this embodiment mode or a flexible substrate such as a film may also be used. As a plastic substrate, a substrate formed of PET (polyethylene terephthalate), PEN (polyethylene naphthalate), or PES (polyether sulfone) may be used, and as a flexible substrate, a substrate formed of a synthetic resin such as acrylic can be used. Since a display device manufactured in this embodiment mode has a structure in which light from a light-emitting element is extracted through the substrate 100, the substrate 100 is required to have a light-transmitting property.

As the base film, silicon oxide, silicone nitride, silicon oxynitride, silicon nitride oxide, or the like can be used. In addition, the base film may be a single layer or have a staked layer structure including two or three layers.

Subsequently, a semiconductor film is formed over the base film. The semiconductor film may be formed by various methods such as a sputtering method, an LPCVD method, and a plasma CVD method to be 25 to 200 nm thick (preferably, 30 to 150 nm thick). In this embodiment mode, it is preferable to use a crystalline semiconductor film formed through crystallization of an amorphous semiconductor film by laser irradiation.

A material for forming the semiconductor film can be an amorphous semiconductor (hereinafter also referred to as “AS”) formed by a vapor phase growth method or a sputtering method using a semiconductor material gas typified by silane or germane, a polycrystalline semiconductor formed by crystallization of an amorphous semiconductor using light energy or thermal energy, a semi-amorphous semiconductor (also referred to as microcrystal and hereinafter also referred to as “SAS”), or the like.

SAS is a semiconductor having an intermediate structure between amorphous and crystalline (including single crystal and polycrystalline) structures and a third state which is stable in free energy. Moreover, SAS includes a crystalline region with a short-distance order and lattice distortion. SAS is formed by glow discharge decomposition (plasma CVD) of a gas containing silicon. As the gas containing silicon, SiH₄ can be used, and in addition, Si₂H₆, SiH₂Cl₂, SiHCl₃, SiCl₄, SiF₄ and the like can also be used. Further, F₂ and GeF₄ may be mixed. The gas containing silicon may be diluted with H₂, or H₂ and one or a plurality of rare gas elements of He, Ar, Kr, and Ne. A rare element such as helium, argon, krypton, or neon is made to be contained to promote lattice distortion, whereby favorable SAS with increased stability can be obtained. An SAS layer formed by using a hydrogen based gas can be stacked over an SAS layer formed by using a fluorine based gas as the semiconductor film.

Hydrogenated amorphous silicon may be typically used as an amorphous semiconductor, while polysilicon and the like may be typically used as a crystalline semiconductor. Polysilicon (polycrystalline silicon) includes so-called high-temperature polysilicon formed using polysilicon as a main material, which is formed at processing temperatures of greater than or equal to 800° C.; so-called low-temperature polysilicon formed using polysilicon as a main material, which is formed at processing temperatures of less than or equal to 600° C.; polysilicon crystallized by addition of an element which promotes crystallization; and the like. It is needless to say that a semi-amorphous semiconductor or a semiconductor containing a crystal phase in part thereof may also be used as described above.

In the case where a crystalline semiconductor film is used for the semiconductor film, the crystalline semiconductor film may be formed by a known method such as a laser crystallization method, a thermal crystallization method, and a thermal crystallization method using an element such as nickel which promotes crystallization. Further, a microcrystalline semiconductor that is SAS may be crystallized by laser irradiation, for enhancing crystallinity. In the case where an element which promotes crystallization is not used, before irradiation of the amorphous semiconductor film with a laser beam, the amorphous semiconductor film is heated at 500° C. for one hour in a nitrogen atmosphere to discharge hydrogen so that the hydrogen concentration in the amorphous semiconductor film is less than or equal to 1×10²⁰ atoms/cm³. This is because, if the amorphous semiconductor film contains much hydrogen, the amorphous semiconductor film may be broken by laser beam irradiation. Heat treatment for crystallization may be performed with the use of a heating furnace, laser irradiation, irradiation with light emitted from a lamp (also referred to as a lamp annealing), or the like. As a heating method, an RTA method such as a GRTA (Gas Rapid Thermal Anneal) method or an LRTA (Lamp Rapid Thermal Anneal) method may be used. A GRTA method is a method in which heat treatment is performed by a high-temperature gas whereas an LRTA method is a method in which heat treatment is performed by light emitted from a lamp.

In a crystallization process in which an amorphous semiconductor layer is crystallized to form a crystalline semiconductor layer, an element which promotes crystallization (also referred to as a catalytic element or a metal element) is added to an amorphous semiconductor layer, and crystallization is performed by heat treatment (at 550 to 750° C. for 3 minutes to 24 hours). As a metal element which promotes crystallization of silicon, one or a plurality of kinds of metal such as iron (Fe), nickel (Ni), cobalt (Co), ruthenium (Ru), rhodium (Rh), palladium (Pd), osmium (Os), iridium (Ir), platinum (Pt), copper (Cu), and gold (Au) can be used.

A method for introducing a metal element into the amorphous semiconductor film is not particularly limited as long as it is a method for introducing the metal element over the surface of or inside the amorphous semiconductor film. For example, a sputtering method, a CVD method, a plasma treatment method (also including a plasma CVD method), an adsorption method, or a method of applying a solution of metal salt can be used. Among them, a method using a solution is simple and advantageous in that the concentration of the metal element can be easily controlled. At this time, it is desirable to form an oxide film by UV light irradiation in an oxygen atmosphere, a thermal oxidation method, treatment with ozone water containing hydroxyl radical or hydrogen peroxide, or the like so that wettability of the surface of the amorphous semiconductor film is improved, and an aqueous solution is diffused over the entire surface of the amorphous semiconductor film.

In order to remove or reduce the element which promotes crystallization from the crystalline semiconductor layer, a semiconductor layer containing an impurity element is formed to be in contact with the crystalline semiconductor layer and is made to function as a gettering sink. As the impurity element, an impurity element imparting n-type, an impurity element imparting p-type, a rare gas element, or the like can be used. For example, one or a plurality of kinds of elements such as phosphorus (P), nitrogen (N), arsenic (As), antimony (Sb), bismuth (Bi), boron (B), helium (He), neon (Ne), argon (Ar), krypton (Kr), and xenon (Xe) can be used. A semiconductor layer containing a rare gas element is formed over the crystalline semiconductor layer containing the element which promotes crystallization, and heat treatment (at temperatures of 550 to 750° C. for 3 minutes to 24 hours) is performed. The element which promotes crystallization contained in the crystalline semiconductor layer moves into the semiconductor layer containing a rare gas element, and the element which promotes crystallization contained in the crystalline semiconductor layer is removed or reduced. After that, the semiconductor layer containing a rare gas element functioning as the gettering sink is removed.

By scanning a laser beam and the semiconductor film relatively, laser irradiation can be performed. Further, in the laser beam irradiation, a marker may be formed to overlap beams with high precision and control positions for starting and finishing laser beam irradiation. The marker may be formed over the substrate at the same time as the amorphous semiconductor film is formed.

In the case of laser beam irradiation, a continuous wave oscillation laser beam (a CW laser beam) or a pulsed oscillation laser beam (a pulsed laser beam) can be used. As a laser beam that can be used here, a laser beam emitted from one or a plurality of kinds of a gas laser such as an Ar laser, a Kr laser, or an excimer laser; a laser using, as a medium, single crystal YAG, YVO₄, forsterite (Mg₂SiO₄), YAlO₃, or GdVO₄, or polycrystal (ceramic) YAG, Y₂O₃, YVO₄, YAlO₃, or GdVO₄ doped with one or a plurality of kinds of Nd, Yb, Cr, Ti, Ho, Er, Tm, and Ta as a dopant; a glass laser; a ruby laser; an alexandrite laser; a Ti: sapphire laser; a copper vapor laser; and a gold vapor laser can be given. By irradiation with the fundamental wave of such a laser beam or the second harmonic to fourth harmonic laser beam of the fundamental wave, a large grain crystal can be obtained. For example, the second harmonic (532 nm) or the third harmonic (355 nm) of an Nd:YVO₄ laser beam (the fundamental wave: 1064 nm) can be used. As for an Nd:YVO₄ laser, either continuous wave oscillation or pulsed oscillation can be performed. In the case of continuous wave oscillation, the power density of the laser beam needs to be approximately 0.01 to 100 MW/cm² (preferably 0.1 to 10 MW/cm²). Then, irradiation is carried out at a scanning rate of approximately 10 to 2000 cm/sec.

Further, a laser using, as a medium, single crystal YAG, YVO₄, forsterite (Mg₂SiO₄), YAlO₃, or GdVO₄, or polycrystal (ceramic) YAG, Y₂O₃, YVO₄, YAlO₃, or GdVO₄ doped with one or a plurality of kinds of Nd, Yb, Cr, Ti, Ho, Er, Tm and Ta as a dopant; an Ar ion laser; or a Ti: sapphire laser can perform continuous wave oscillation. In addition, pulsed oscillation at a repetition rate of greater than or equal to 10 MHz is also possible by Q-switch operation, mode locking, or the like. Through pulsed oscillation of a laser beam at a repetition rate of greater than or equal to 10 MHz, the semiconductor film is irradiated with the next pulse after the semiconductor film is melted by a laser beam and before the film is solidified. Accordingly, differing from the case where a pulsed laser at a lower repetition rate is used, the solid-liquid interface can be continuously moved in the semiconductor film, and a crystal grain grown continuously toward the scanning direction can be obtained.

The use of ceramics (polycrystal) as a medium allows the medium to be formed into a free shape at low cost in a short time. Although a columnar medium of several mm in diameter and several tens of mm in length is usually used in the case of single crystal, larger mediums can be formed in the case of ceramics.

Since the concentration of the dopant such as Nd or Yb in the medium, which directly contributes to light emission, is difficult to be changed significantly both in single crystal and polycrystal, improvement in laser beam output by increase in the concentration of the dopant has a certain level of limitation. However, in the case of ceramics, drastic improvement in output can be expected because the size of the medium can be significantly increased compared with the case of single crystal.

Further, in the case of ceramics, a medium having a parallelepiped shape or a rectangular parallelepiped shape can be easily formed. When a medium having such a shape is used and oscillation light goes in zigzag in the medium, an oscillation light path can be longer. Accordingly, amplification is increased and oscillation with high output is possible. Since a laser beam emitted from the medium having such a shape has a cross section of a quadrangular shape when being emitted, a linear beam can be easily shaped compared with the case of a circular beam. The laser beam emitted in such a manner is shaped by using an optical system; accordingly, a linear beam having a short side of less than or equal to 1 mm and a long side of several mm to several m can be easily obtained. In addition, by uniform irradiation of the medium with excited light, a linear beam has a uniform energy distribution in a long side direction. Further, the semiconductor film may be irradiated with a laser beam at an incident angle θ (0<θ<90°) with respect to the semiconductor film, whereby an interference of the laser beam can be prevented.

By irradiation of the semiconductor film with this linear beam, the entire surface of the semiconductor film can be annealed more uniformly. In the case where uniform annealing is required from one end to the other end of the linear beam, slits may be provided for the both ends so as to shield a portion where energy is attenuated.

When the thus obtained linear beam with uniform intensity is used to anneal the semiconductor film and this semiconductor film is used to manufacture a display device, the display device has favorable and uniform characteristics.

The semiconductor film may be irradiated with a laser beam in an inert gas atmosphere such as a rare gas or nitrogen as well. Accordingly, roughness of the surface of the semiconductor film can be prevented by laser beam irradiation, and variation of threshold voltage due to variation of interface state density can be prevented.

The amorphous semiconductor film may be crystallized by a combination of heat treatment and laser beam irradiation, or one of heat treatment and laser beam irradiation may be performed a plurality of times.

In this embodiment mode, an amorphous semiconductor film is formed over the base film 101b and crystallized, whereby a crystalline semiconductor film is formed.

After an oxide film formed over the amorphous semiconductor film is removed, an oxide film is formed to be 1 to 5 nm thick by UV light irradiation in an oxygen atmosphere, a thermal oxidization method, treatment with ozone water containing hydroxyl radical or hydrogen peroxide solution, or the like. In this embodiment mode, Ni is used as an element which promotes crystallization. An aqueous solution containing 10 ppm of Ni acetate is applied by a spin coating method.

In this embodiment mode, after heat treatment is performed by an RTA method at 750° C. for three minutes, the oxide film formed over the semiconductor film is removed and laser beam irradiation is performed. The amorphous semiconductor film is crystallized by the aforementioned crystallization treatment, whereby the crystalline semiconductor film is formed.

In the case where crystallization is performed with the use of a metal element, a gettering step is performed to reduce or remove the metal element. In this embodiment mode, the metal element is captured by an amorphous semiconductor film as a gettering sink. First, an oxide film is formed over the crystalline semiconductor film by UV light irradiation in an oxygen atmosphere, a thermal oxidation method, treatment with ozone water containing hydroxyl radical or hydrogen peroxide, or the like. The oxide film is preferably made thick by heat treatment. Then, an amorphous semiconductor film is formed to be 50 nm thick by a plasma CVD method (a condition of this embodiment mode: 350 W, 35 Pa, and deposition gas: SiH₄ (the flow rate: 5 sccm) and Ar (the flow rate: 1000 sccm)).

Thereafter, heat treatment is performed by an RTA method at 744° C. for three minutes to reduce or remove the metal element. Heat treatment may also be performed in a nitrogen atmosphere. Then, the amorphous semiconductor film serving as a gettering sink and the oxide film formed over the amorphous semiconductor film are removed with hydrofluoric acid or the like, whereby a crystalline semiconductor film in which the metal element is reduced or removed can be obtained. In this embodiment mode, the amorphous semiconductor film serving as a gettering sink is removed with the use of TMAH (Tetramethyl Ammonium Hydroxide).

The semiconductor film obtained as described above may be doped with the slight amount of impurity elements (boron or phosphorus) for controlling threshold voltage of a thin film transistor. This doping of the impurity elements may also be performed to the amorphous semiconductor film, before the crystallization step. When the semiconductor film in an amorphous state is doped with the impurity elements, the impurities can also be activated by subsequent heat treatment for crystallization. Further, defects and the like generated in doping can be improved as well.

Subsequently, the crystalline semiconductor film is etched into a desired shape, whereby a semiconductor layer is formed.

An etching process may employ either plasma etching (dry etching) or wet etching. In the case a large-area substrate is processed, plasma etching is more suitable. As an etching gas, a fluorine based gas such as CF₄ or NF₃, or a chlorine based gas such as Cl₂ or BCl₃ is used, to which an inert gas such as He or Ar may be appropriately added. When an etching process by atmospheric pressure discharge is employed, local electric discharge can also be realized, which does not require a mask layer to be formed over the entire surface of the substrate.

In the present invention, a conductive layer for forming a wiring layer or an electrode layer, a mask layer for forming a predetermined pattern, or the like may be formed by a method capable of selectively forming a pattern, such as a droplet-discharging method. In the droplet-discharging (ejecting) method (also referred to as an inkjet method in accordance with the system thereof), liquid of a composition prepared for a specific purpose is selectively discharged (ejected), and a predetermined pattern (a conductive layer, an insulating layer, or the like) is formed. At that time, treatment for controlling wettability or adhesion may be performed to a region where a pattern is formed. Additionally, a method capable of transferring or drawing a pattern, for example, a printing method (a method for forming a pattern, such as screen printing or offset printing), a dispenser method, or the like can also be used.

In this embodiment mode, a resin material such as an epoxy resin, an acrylic resin, a phenol resin, a novolac resin, a melamine resin, or an urethane resin is used as a mask. Alternatively, an organic material such as benzocyclobutene, parylene, fluorinated arylene ether, or polyimide having a light transmitting property; a compound material formed by polymerization of siloxane-based polymers or the like; a composition material containing a water-soluble homopolymer and a water-soluble copolymer; and the like can also be used. Further alternatively, a commercially available resist material including a photosensitive agent may also be used. For example, a positive resist or a negative resist can be used. When a droplet-discharging method is used with any material, the surface tension and the viscosity of a material are appropriately adjusted through the control of the solvent concentration, addition of a surfactant, and the like.

A gate insulating layer 107 covering the semiconductor layer is formed. The gate insulating layer 107 is formed using an insulating film containing silicon to be 10 to 150 nm thick by a plasma CVD method, a sputtering method, or the like. The gate insulating layer 107 may be formed by using a known material such as an oxide material or a nitride material of silicon, typified by silicon nitride, silicon oxide, silicon oxynitride, and silicon nitride oxide, and may be a stacked layer or a single layer. For example, the insulating layer can be a stacked layer of three layers including a silicon nitride film, a silicon oxide film, and a silicon nitride film, a single layer of a silicon oxynitride film, or the like.

Subsequently, a gate electrode layer is formed over the gate insulating layer 107. The gate electrode layer can be formed by a sputtering method, an evaporation method, a CVD method, or the like. The gate electrode layer may be formed using an element such as tantalum (Ta), tungsten (W), titanium (Ti), molybdenum (Mo), aluminum (Al), copper (Cu), chromium (Cr), or neodymium (Nd), or an alloy material or a compound material containing these elements as its main component. Further, as the gate electrode layer, a semiconductor film typified by a polycrystalline silicon film doped with an impurity element such as phosphorus can be used, or AgPdCu alloy may be used. In addition, the gate electrode layer may be a single layer or a stacked layer.

In this embodiment mode, the gate electrode layer is formed into a tapered shape; however, the present invention is not limited thereto. The gate electrode layer may have a stacked layer structure, where only one layer has a tapered shape while the other has a perpendicular side surface by anisotropic etching. As described in this embodiment mode, the taper angles may be different or the same between the stacked gate electrode layers. With the tapered shape, coverage of a film to be stacked thereover is improved and defects are reduced, whereby reliability is enhanced.

The gate insulating layer 107 may be etched to some extent and reduced in thickness (so-called film decrease) by the etching step for forming the gate electrode layer.

An impurity element is added to the semiconductor layer to form an impurity region. The impurity region can be formed as a high-concentration impurity region and a low-concentration impurity region through the control of the concentration of the impurity element. A thin film transistor having a low-concentration impurity region is referred to as a thin film transistor having an LDD (Light doped drain) structure. In addition, the low-concentration impurity region can be formed so as to overlap with the gate electrode. Such a thin film transistor is referred to as a thin film transistor having a GOLD (Gate Overlapped LDD) structure. The polarity of the thin film transistor is made n-type through addition of phosphorus (P) or the like to an impurity region thereof. In the case where a p-type thin film transistor is formed, boron (B) or the like may be added.

In this embodiment mode, a region of the impurity region, which overlaps with the gate electrode layer with the gate insulating layer interposed therebetween, is denoted as a Lov region. Further, a region of the impurity region, which does not overlap with the gate electrode layer with the gate insulating layer interposed therebetween, is denoted as a Loff region. In FIG. 7B, the impurity region is shown by hatching and a blank space. This does not mean that the blank space is not doped with an impurity element, but makes it easy to understand that the concentration distribution of the impurity element in this region reflects the mask and the doping condition. It is to be noted that this is the same in other drawings of this specification.

In order to activate the impurity element, heat treatment, strong light irradiation, or laser beam irradiation may be performed. At the same time as the activation, plasma damage to the gate insulating layer and plasma damage to the interface between the gate insulating layer and the semiconductor layer can be recovered.

Subsequently, a first interlayer insulating layer which covers the gate electrode layer and the gate insulating layer is formed. In this embodiment mode, a stacked layer structure of insulating films 167 and 168 is employed. As the insulating films 167 and 168, a silicon nitride film, a silicon nitride oxide film, a silicon oxynitride film, a silicon oxide film, or the like can be formed by a sputtering method or a plasma CVD method. Alternatively, other insulating films containing silicon may also be used as a single layer or a stacked layer structure including three or more layers.

Further, heat treatment is performed at 300 to 550° C. for 1 to 12 hours in a nitrogen atmosphere, and the semiconductor layer is hydrogenated. Preferably, this heat treatment is performed at 400 to 500° C. Through this step, dangling bonds in the semiconductor layer are terminated by hydrogen contained in the insulating film 167 that is an interlayer insulating layer. In this embodiment mode, heat treatment is performed at 410° C.

In addition, the insulating films 167 and 168 can also be formed using a material of aluminum nitride (AlN), aluminum oxynitride (AlON), aluminum nitride oxide containing more nitrogen than oxygen (AlNO), aluminum oxide, diamond-like carbon (DLC), nitrogen-containing carbon (CN), polysilazane, or other substances containing an inorganic insulating material. A material containing siloxane may also be used. Further, an organic insulating material such as polyimide, acrylic, polyamide, polyimide amide, resist, or benzocyclobutene may also be used. In addition, an oxazole resin can be used, and for example, photo-curable type polybenzoxazole or the like can be used.

Subsequently, a contact hole (opening), which reaches the semiconductor layer, is formed in the insulating films 167 and 168, and the gate insulating layer 107 with the use of a mask formed of a resist. A conductive film is formed so as to cover the opening, and the conductive film is etched, whereby a source electrode layer or a drain electrode layer is formed, which is electrically connected to part of a source region or a drain region. In order to form the source electrode layer or the drain electrode layer, a conductive film is formed by a PVD method, a CVD method, an evaporation method, or the like, and the conductive film is etched into a desired shape. Further, the conductive film can be selectively formed in a predetermined position by a droplet-discharging method, a printing method, a dispenser method, an electrolytic plating method, or the like. A reflow method or a damascene method may also be used. The source electrode layer or the drain electrode layer is formed using an element such as Ag, Au, Cu, Ni, Pt, Pd, Ir, Rh, W, Al, Ta, Mo, Cd, Zn, Fe, Ti, Si, Ge, Zr, or Ba, or alloy or nitride thereof. In addition, a stacked layer structure of these materials may also be used.

Through the above steps, an active matrix substrate can be manufactured, in which a p-channel thin film transistor 285 having a p-type impurity region in a Lov region and an n-channel thin film transistor 275 having an n-channel impurity region in a Lov region are provided in a peripheral driver circuit region 204; and a multi-channel type n-channel thin film transistor 265 having an n-type impurity region in a Loff region and a p-channel thin film transistor 255 having a p-type impurity region in a Lov region are provided in a pixel region 206.

The structure of the thin film transistor in the pixel region is not limited to this embodiment mode, and a single gate structure in which one channel forming region is formed, a double gate structure in which two channel forming regions are formed, or a triple gate structure in which three channel forming regions are formed may be employed. Further, the thin film transistor in the peripheral driver circuit region may also employ a single gate structure, a double gate structure, or a triple gate structure.

Next, an insulating film 181 is formed as a second interlayer insulating layer. In FIGS. 7A and 7B, a separation region 201 for separation by scribing, an external terminal connection region 202 to which an FPC is attached, a wiring region 203 that is a lead wiring region for the peripheral portion, the peripheral driver circuit region 204, and the pixel region 206 are provided. Wirings 179a and 179b are provided in the wiring region 203, and a terminal electrode layer 178 connected to an external terminal is provided in the external terminal connection region 202.

The insulating film 181 can be formed using a material of silicon oxide, silicone nitride, silicon oxynitride, silicon nitride oxide, aluminum nitride (AlN), aluminum oxide containing nitrogen (also referred to as aluminum oxynitride) (AlON), aluminum nitride containing oxygen (also referred to as aluminum nitride oxide) (AlNO), aluminium oxide, diamond-like carbon (DLC), nitrogen-containing carbon (CN), PSG (phosphorus glass), BPSG (boron phosphorus glass), alumina, or other substances containing an inorganic insulating material. In addition, a siloxane resin may also be used. Further, a photosensitive or non-photosensitive organic insulating material such as polyimide, acrylic, polyamide, polyimide amide, resist, benzocyclobutene, polysilazane, or a low-dielectric material (Low-k material) can also be used. In addition, an oxazole resin can be used, and for example, photo-curable type polybenzoxazole or the like can be used. An interlayer insulating layer provided for planarization is required to have high heat resistance, a high insulating property, and high planarity. Thus, the insulating film 181 is preferably formed by a coating method typified by a spin coating method.

The insulating film 181 can be formed by a dipping method, spray coating, a doctor knife, a roll coater, a curtain coater, a knife coater, a CVD method, an evaporation method, or the like. The insulating film 181 may also be formed by a droplet-discharging method. In the case of a droplet-discharging method, a material solution can be saved. In addition, a method capable of transferring or drawing a pattern like a droplet-discharging method such as a printing method (a method for forming a pattern, such as screen printing or offset printing) or a dispenser method can also be used.

A minute opening, that is, a contact hole is formed in the insulating film 181 in the pixel region 206.

Then, a first electrode layer 185 (also referred to as a pixel electrode layer) is formed so as to be in contact with the source electrode layer or the drain electrode layer. The first electrode layer 185 functions as an anode or a cathode, and may be formed using an element such as Ti, Ni, W, Cr, Pt, Zn, Sn, In, or Mo; an alloy material or a compound material containing the above elements as its main component such as TiN, TiSi_{X}N_{Y}, WSi_{X}, WN_{X}, WSi_{X}N_{Y}, or NbN; or a stacked film thereof with a total thickness of 100 to 800 nm.

In this embodiment mode, a light-emitting element is used as a display element, and the first electrode layer 185 has a light-transmitting property because light from the light-emitting element is extracted from the first electrode layer 185 side. The first electrode layer 185 is formed using a transparent conductive film which is etched into a desired shape.

In the present invention, the first electrode layer 185 that is a light-transmitting electrode layer may be specifically formed using a transparent conductive film formed of a light-transmitting conductive material, and indium oxide containing tungsten oxide, indium zinc oxide containing tungsten oxide, indium oxide containing titanium oxide, indium tin oxide containing titanium oxide, or the like can be used. It is needless to say that indium tin oxide (ITO), indium zinc oxide (IZO), indium tin oxide doped with silicon oxide (ITSO), or the like can also be used.

In addition, even in the case of a non-light-transmitting material such as a metal film, when the film thickness is made thin (preferably, about 5 to 30 nm) so as to be able to transmit light, light can be emitted from the first electrode layer 185. As a metal thin film that can be used for the first electrode layer 185, a conductive film formed of titanium, tungsten, nickel, gold, platinum, silver, aluminum, magnesium, calcium, lithium, or alloy thereof, or the like can be used.

The first electrode layer 185 can be formed by an evaporation method, a sputtering method, a CVD method, a printing method, a dispenser method, a droplet-discharging method, or the like. In this embodiment mode, the first electrode layer 185 is formed by a sputtering method using indium zinc oxide containing tungsten oxide. The first electrode layer 185 is preferably used with a total thickness of 100 to 800 nm.

The first electrode layer 185 may be cleaned or polished by a CMP method or with the use of a polyvinyl alcohol based porous material so that the surface thereof is planarized. In addition, after polishing using a CMP method, ultraviolet ray irradiation, oxygen plasma treatment, or the like may be performed on the surface of the first electrode layer 185.

Heat treatment may be performed after the first electrode layer 185 is formed. By the heat treatment, moisture contained in the first electrode layer 185 is discharged. Accordingly, degasification or the like is not caused in the first electrode layer 185. Thus, even when a light-emitting material which is easily deteriorated by moisture is formed over the first electrode layer, the light-emitting material is not deteriorated; therefore, a highly reliable display device can be manufactured.

Next, an insulating layer 186 (also referred to as a partition wall or a barrier) is formed to cover the edge of the first electrode layer 185 and the source electrode layer or the drain electrode layer.

The insulating layer 186 can be formed using silicon oxide, silicon nitride, silicon oxynitride, silicon nitride oxide, or the like, and may have a single layer structure or a stacked layer structure including two or three layers. In addition, as other materials for the insulating layer 186, a material of aluminum nitride, aluminum oxynitride containing more oxygen than nitrogen, aluminum nitride oxide containing more nitrogen than oxygen, aluminum oxide, diamond-like carbon (DLC), nitrogen-containing carbon, polysilazane, or other substances containing an inorganic insulating material can be used. A material containing siloxane may also be used. Further, a photosensitive or non-photosensitive organic insulating material such as polyimide, acrylic, polyamide, polyimide amide, resist, or benzocyclobutene may also be used. In addition, an oxazole resin can be used, and for example, photo-curable type polybenzoxazole or the like can be used.

The insulating layer 186 can be formed by a sputtering method, a CVD method such as a PVD (Physical Vapor deposition) method, a low-pressure CVD (LPCVD) method, or a plasma CVD method, a droplet-discharging method capable of selectively forming a pattern, a method capable of transferring or drawing a pattern such as a printing method (a method for forming a pattern such as screen printing or offset printing), a dispenser method, a coating method such as a spin coating method, or a dipping method.

An etching process for forming a desired shape may employ either plasma etching (dry etching) or wet etching. In the case where a large-area substrate is processed, plasma etching is more suitable. As an etching gas, a fluorine based gas such as CF₄ or NF₃, or a chlorine based gas such as Cl₂, or BCl₃ is used, to which an inert gas such as He or Ar may be appropriately added. When an etching process by atmospheric pressure discharge is employed, local electric discharge can also be realized, which does not require a mask layer to be formed over the entire surface of the substrate.

As shown in FIG. 7A, in a connection region 205, a wiring layer formed of the same material and through the same step as those of a second electrode layer is electrically connected to a wiring layer formed of the same material and through the same step as those of the gate electrode layer.

A light-emitting layer 188 is formed over the first electrode layer 185. Although only one pixel is shown in FIG. 7B, light-emitting layers corresponding to each color of R (red), G (green) and B (blue) are formed in this embodiment mode. The light-emitting layer 188 may be manufactured as described in Embodiment Mode 1.

The light-emitting layer 188 manufactured by using the present invention contains a light-emitting material fixed by a binder. In this embodiment mode, the light-emitting material in a particle state is irradiated with light, the light-emitting material is modified, and crystallinity of the light-emitting material is improved. By light irradiation, dangling bonds of atoms in the light-emitting material are bonded to each other, whereby defects are reduced and distortion is relieved in the light-emitting material. Therefore, a light-emitting material with favorable crystallinity can be used, whereby luminance and light-emitting efficiency of the light-emitting element can be improved and power consumption can also be reduced. Therefore, a display device with high performance and high reliability can be manufactured.

Subsequently, a second electrode layer 189 formed of a conductive film is provided over the light-emitting layer 188. As the second electrode layer 189, Al, Ag, Li, Ca, or an alloy or a compound thereof such as MgAg, MgIn, AlLi, or CaF₂, or calcium nitride may be used. In this manner, a light-emitting element 190 including the first electrode layer 185, the light-emitting layer 188, and the second electrode layer 189 is formed (see FIG. 7B).

In the display device of this embodiment mode shown in FIGS. 7A and 7B, light from the light-emitting element 190 is emitted from the first electrode layer 185 side to be transmitted in a direction indicated by an arrow in FIG. 7B.

In this embodiment mode, an insulating layer may be provided as a passivation film (a protective film) over the second electrode layer 189. It is effective to provide a passivation film so as to cover the second electrode layer 189 as described above. The passivation film may be formed using an insulating film including silicon nitride, silicon oxide, silicon oxynitride, silicon nitride oxide, aluminum nitride, aluminum oxynitride, aluminum nitride oxide containing more nitrogen than oxygen, aluminum oxide, diamond-like carbon (DLC), or nitrogen-containing carbon, and a single layer or a stacked layer of the insulating films can be used. Alternatively, a siloxane resin may also be used.

At this time, it is preferable to form the passivation film by using a film with favorable coverage, and it is effective to use a carbon film, particularly, a DLC film for the passivation film. A DLC film can be formed in the temperature range from room temperature to less than or equal to 100° C.; therefore, it can also be formed easily over the light-emitting layer 188 with low heat resistance. A DLC film can be formed by a plasma CVD method (typically, an RF plasma CVD method, a microwave CVD method, an electron cyclotron resonance (ECR) CVD method, a heat filament CVD method, or the like), a combustion method, a sputtering method, an ion beam evaporation method, a laser evaporation method, or the like. As a reaction gas for deposition, a hydrogen gas and a carbon hydride-based gas (for example, CH₄, C₂H₂, C₆H₆, and the like) are used to be ionized by glow discharge, and the ions are accelerated to impact against a cathode to which negative self-bias voltage is applied. Further, a CN film may be formed with the use of a C₂H₄ gas and a N₂ gas as a reaction gas. A DLC film has high blocking effect against oxygen; therefore oxidization of the light-emitting layer 188 can be suppressed. Accordingly, a problem such as oxidation of the light-emitting layer 188 during a subsequent sealing step can be prevented.

The substrate 100 over which the light-emitting element 190 is formed and a sealing substrate 195 are firmly attached to each other with a sealing material 192, whereby the light-emitting element is sealed (see FIGS. 7A and 7B). As the sealing material 192, typically, a visible light curable resin, an ultraviolet ray curable resin, or a thermosetting resin is preferably used. For example, a bisphenol-A liquid resin, a bisphenol-A solid resin, a bromine-containing epoxy resin, a bisphenol-F resin, a bisphenol-AD resin, a phenol resin, a cresol resin, a novolac resin, a cycloaliphatic epoxy resin, an Epi-Bis type epoxy resin, a glycidyl ester resin, a glycidyl amine-based resin, a heterocyclic epoxy resin, a modified epoxy resin, or the like can be used. It is to be noted that a region surrounded by the sealing material may be filled with a filler 193, and nitrogen or the like may be filled and sealed by sealing in a nitrogen atmosphere. Since a bottom emission type is employed in this embodiment mode, the filler 193 is not required to transmit light. However, in the case where light is extracted through the filler 193, the filler is required to transmit light. Typically, a visible light curable epoxy resin, an ultraviolet ray curable epoxy resin, or a thermosetting epoxy resin may be used. Through the aforementioned steps, a display device having a display function using the light-emitting element of this embodiment mode is completed. Further, the filler may be dripped in a liquid state to fill the display device. Through the use of a hygroscopic substance like a drying agent as the filler, further moisture absorbing effect can be obtained, whereby the element can be prevented from deteriorating.

A drying agent is provided in an EL display panel to prevent deterioration due to moisture in the element. In this embodiment mode, the drying agent is provided in a concave portion that is formed so as to surround the pixel region on the sealing substrate, whereby a thin design is not hindered. Further, the drying agent is also formed in a region corresponding to a gate wiring layer so that a moisture absorbing area becomes wide; thus, moisture can be effectively absorbed. In addition, a drying agent is formed over a gate wiring layer which does not emit light from itself; therefore, light extraction efficiency is not decreased, either.

The light-emitting element is sealed by a glass substrate in this embodiment mode. It is to be noted that sealing treatment is treatment for protecting a light-emitting element from moisture, and any of a method for mechanically sealing the light-emitting element by a cover material, a method for sealing the light-emitting element with a thermosetting resin or an ultraviolet ray curable resin, and a method for sealing the light-emitting element by a thin film having a high barrier property such as a metal oxide film or a metal nitride film is used. As the cover material, glass, ceramics, plastics, or metal can be used, and a material which transmits light is required to be used in the case where light is emitted to the cover material side. The cover material and the substrate over which the light-emitting element is formed are attached to each other with a sealing material such as a thermosetting resin or an ultraviolet ray curable resin, and a sealed space is formed through curing of the resin by heat treatment or ultraviolet ray irradiation treatment. It is also effective to provide a moisture absorbing material typified by barium oxide in this sealed space. This moisture absorbing material may be provided over and in contact with the sealing material, or over or in the periphery of the partition wall so as not to shield light from the light-emitting element. Further, the space between the cover material and the substrate over which the light-emitting element is formed can be filled with a thermosetting resin or an ultraviolet ray curable resin. In this case, it is effective to add a moisture absorbing material typified by barium oxide in the thermosetting resin or the ultraviolet ray curable resin.

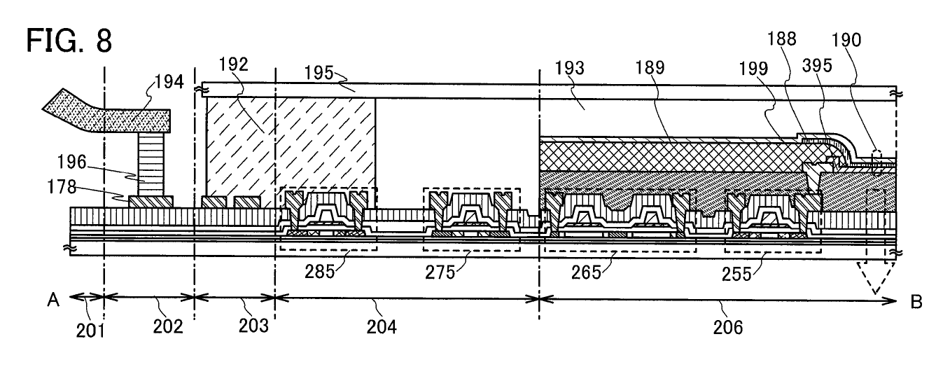

FIG. 8 shows an example in which, in the display device shown in FIGS. 7A and 7B manufactured in this embodiment mode, the source electrode layer or the drain electrode layer and the first electrode layer are not directly in contact with each other to be electrically connected, but connected to each other through a wiring layer. In a display device of FIG. 8, a source electrode layer or a drain electrode layer of a thin film transistor for driving a light-emitting element and a first electrode layer 395 are electrically connected to each other through a wiring layer 199. In FIG. 8, part of the first electrode layer 395 is stacked over the wiring layer 199 to be connected; however, the first electrode layer 395 may be formed first, and then, the wiring layer 199 may be formed over and to be in contact with the first electrode layer 395.

In this embodiment mode, the terminal electrode layer 178 is connected to an FPC 194 through an anisotropic conductive layer 196 in the external terminal connection region 202, and electrically connected to an external portion. In addition, as shown in FIG. 7A that is a top view of the display device, the display device manufactured in this embodiment mode includes a peripheral driver circuit region 207 and a peripheral driver circuit region 208 each including a scanning line driver circuit in addition to the peripheral driver circuit region 204 and the peripheral driver circuit region 209 each including a signal line driver circuit.

The circuit as described above is formed in this embodiment mode; however, the present invention is not limited thereto. An IC chip may be mounted by the aforementioned COG method or TAB method as the peripheral driver circuit. Further, single or plural gate line driver circuits and source line driver circuits may be provided.

In the display device of the present invention, a driving method for image display is not particularly limited, and for example, a dot sequential driving method, a line sequential driving method, an area sequential driving method, or the like may be used. Typically, a line sequential driving method may be used, and a time division gray scale driving method and an area gray scale driving method may be appropriately used. Further, a video signal input to the source line of the display device may be an analog signal or a digital signal. The driver circuit and the like may be appropriately designed in accordance with the video signal.

By light irradiation to the light-emitting material used in the present invention, dangling bonds of atoms in the light-emitting material are bonded to each other, whereby defects are reduced and crystallinity is improved. In addition, through the use of a light-emitting element using such a light-emitting material with favorable crystallinity, low-voltage driving, high luminance, and high light-emitting efficiency can be obtained.

Accordingly, by using the present invention, a display device with low power consumption, high performance, and high reliability can be manufactured at low cost with high productivity.

### Embodiment Mode 5

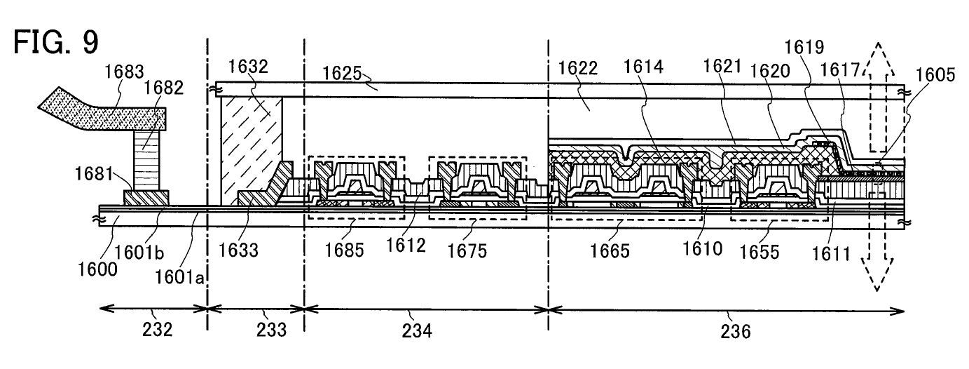

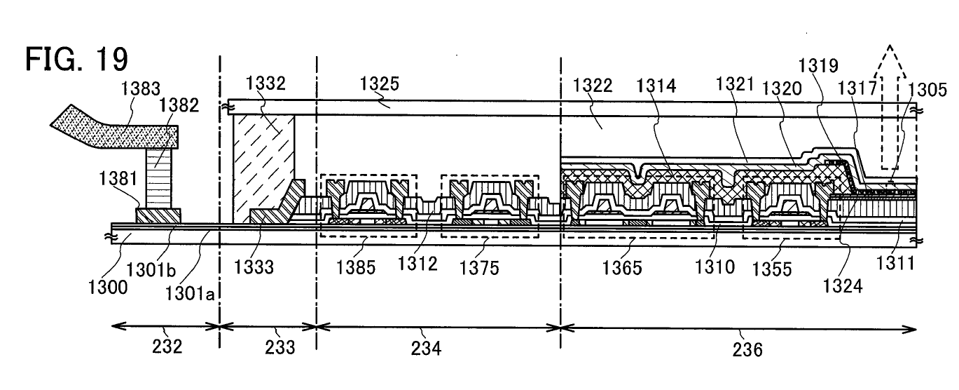

A display device having a light-emitting element can be formed by employing the present invention. Light from the light-emitting element is emitted in any manner of bottom emission, top emission, and dual emission. This embodiment mode will explain examples of a dual emission type and a top emission type with reference to FIGS. 9 and 19. Further, this embodiment mode will show an example in which the second interlayer insulating layer (insulating film 181) is not formed in the display device manufactured in Embodiment Mode 4. Therefore, the same portions or portions having the similar functions will not be repeatedly explained.

FIG. 9 shows a display device, which includes an element substrate 1600, thin film transistors 1655, 1665, 1675, and 1685, a first electrode layer 1617, a light-emitting layer 1619, a second electrode layer 1620, an insulating film 1621, a filler 1622, a sealing material 1632, insulating films 1601a and 1601b, a gate insulating layer 1610, insulating films 1611 and 1612, an insulating layer 1614, a sealing substrate 1625, a wiring layer 1633, a terminal electrode layer 1681, an anisotropic conductive layer 1682, and an FPC 1683. The display device also includes an external terminal connection region 232, a sealing region 233, a peripheral driver circuit region 234, and a pixel region 236. The filler 1622 can be formed by a droplet-discharging method using a material in a state of a liquid composition. The element substrate 1600 over which the filler is formed by the droplet-discharging method and the sealing substrate 1625 are attached to each other to seal the light-emitting display device.

The light-emitting layer 1619 manufactured by using the present invention contains a light-emitting material fixed by a binder. In this embodiment mode, the light-emitting material in a particle state is irradiated with light, the light-emitting material is modified, and crystallinity of the light-emitting material is improved. By light irradiation, dangling bonds of atoms in the light-emitting material are bonded to each other, whereby defects are reduced and distortion is relieved in the light-emitting material. Therefore, a light-emitting material with favorable crystallinity can be used, whereby luminance and light-emitting efficiency of the light-emitting element can be improved and power consumption can also be reduced. Therefore, a display device with high performance and high reliability can be manufactured.

The display device of FIG. 9 is a dual emission type, in which light is emitted from both the element substrate 1600 side and the sealing substrate 1625 side in directions indicated by arrows. Thus, a light-transmitting electrode layer is used for each of the first electrode layer 1617 and the second electrode layer 1620.

In this embodiment mode, the first electrode layer 1617 and the second electrode layer 1620, each of which is a light-transmitting electrode layer, may be specifically formed by using a transparent conductive film formed of a light-transmitting conductive material, and indium oxide containing tungsten oxide, indium zinc oxide containing tungsten oxide, indium oxide containing titanium oxide, indium tin oxide containing titanium oxide, or the like can be used. It is needless to say that indium tin oxide (ITO), indium zinc oxide (IZO), indium tin oxide to which silicon oxide is added (ITSO), or the like can be used.

In addition, even in the case of a non-light-transmitting material such as a metal film, when the thickness is made thin (preferably, approximately 5 to 30 nm) so as to be able to transmit light, light can be emitted from the first electrode layer 1617 and the second electrode layer 1620. As a metal thin film that can be used for the first electrode layer 1617 and the second electrode layer 1620, a conductive film formed of titanium, tungsten, nickel, gold, platinum, silver, aluminum, magnesium, calcium, lithium, and alloy thereof; or the like can be used.

As described above, in the display device of FIG. 9, light emitted from a light-emitting element 1605 passes through both the first electrode layer 1617 and the second electrode layer 1620, whereby light is emitted from both sides.

A display device of FIG. 19 has a structure of a top emission type in which light is emitted from a light-emitting element 1305 in a direction indicated by an arrow. FIG. 19 shows a display device, which includes an element substrate 1300, thin film transistors 1355, 1365, 1375, and 1385, a wiring layer 1324, a first electrode layer 1317, a light-emitting layer 1319, a second electrode layer 1320, a protective film 1321, a filler 1322, a sealing material 1332, insulating films 1301a and 1301b, a gate insulating layer 1310, insulating films 1311 and 1312, an insulating layer 1314, a sealing substrate 1325, a wiring layer 1333, a terminal electrode layer 1381, an anisotropic conductive layer 1382, and an FPC 1383.

In each of the display devices shown in FIGS. 9 and 19, the insulating layer stacked over the terminal electrode layer is removed by etching. In a structure where a permeable insulating layer is not provided at the periphery of a terminal electrode layer, reliability is more improved. The display device shown in FIG. 19 includes an external terminal connection region 232, a sealing region 233, a peripheral driver circuit region 234, and a pixel region 236. In the display device of FIG. 19, the wiring layer 1324 which is a reflective metal layer is formed below the first electrode layer 1317, and the first electrode layer 1317 which is a transparent conductive film is formed over the wiring layer 1324 in the above dual emission display device shown in FIG. 9. As the wiring layer 1324, a conductive film formed of titanium, tungsten, nickel, gold, platinum, silver, copper, tantalum, molybdenum, aluminum, magnesium, calcium, lithium, or alloy thereof, or the like may be used as long as the material has reflectiveness. Preferably, a substance having high reflectiveness in a visible light region is used, and a TiN film is used in this embodiment mode. In addition, the first electrode layer 1317 may be formed of a conductive film, and in that case, the wiring layer 1324 having reflectiveness may not be provided.

The second electrode layer 1320 may be specifically formed by using a transparent conductive film formed of a light-transmitting conductive material, and indium oxide containing tungsten oxide, indium zinc oxide containing tungsten oxide, indium oxide containing titanium oxide, indium tin oxide containing titanium oxide, or the like can be used. It is needless to say that indium tin oxide (ITO), indium zinc oxide (IZO), indium tin oxide to which silicon oxide is added (ITSO), or the like can also be used.

In addition, even in the case of a non-light-transmitting material such as a metal film, when the thickness is made thin (preferably, approximately 5 to 30 nm) so as to be able to transmit light, light can be emitted from the second electrode layer 1320. As a metal thin film that can be used for the second electrode layer 1320, a conductive film formed of titanium, tungsten, nickel, gold, platinum, silver, aluminum, magnesium, calcium, lithium, or alloy thereof, or the like can be used. A material similar to those for the second electrode layer 1320 can also be used for the first electrode layer 1317.

A pixel of a display device that can be formed by using a light-emitting element can be driven by a simple matrix mode or an active matrix mode. In addition, either digital driving or analog driving can be employed.

A color filter (colored layer) may be formed on the sealing substrate. The color filter (colored layer) can be formed by an evaporation method or a droplet-discharging method. With the use of the color filter (colored layer), high-definition display can be performed. This is because a broad peak can be modified to be sharp in the emission spectrum of each of R, G, and B by the color filter (colored layer).

Full color display can be performed by formation of a material emitting light of a single color and combination of the material with a color filter or a color conversion layer. The color filter (colored layer) or the color conversion layer may be formed on, for example, a second substrate (a sealing substrate), and the second substrate may be attached to the substrate.

It is needless to say that display of single color emission may also be performed. For example, an area color type display device may be manufactured by using single color emission. The area color type is suitable for a passive matrix display portion, and can mainly display characters and symbols.

The first electrode layers 1617 and 1317 and the second electrode layers 1620 and 1320 can be formed by an evaporation method with resistance heating, an EB evaporation method, a sputtering method, a CVD method, a wet method such as a printing method, a dispenser method, or a droplet-discharging method, or the like. This embodiment mode can be freely combined with Embodiment Modes 1 to 4.

By light irradiation to the light-emitting material used in the present invention, dangling bonds of atoms in the light-emitting material are bonded to each other, whereby defects are reduced and crystallinity is improved. In addition, through the use of a light-emitting element using such a light-emitting material with favorable crystallinity, low-voltage driving, high luminance, and high light-emitting efficiency can be obtained.

Accordingly, by using the present invention, a display device with low power consumption, high performance, and high reliability can be manufactured at low cost with high productivity.

### Embodiment Mode 6

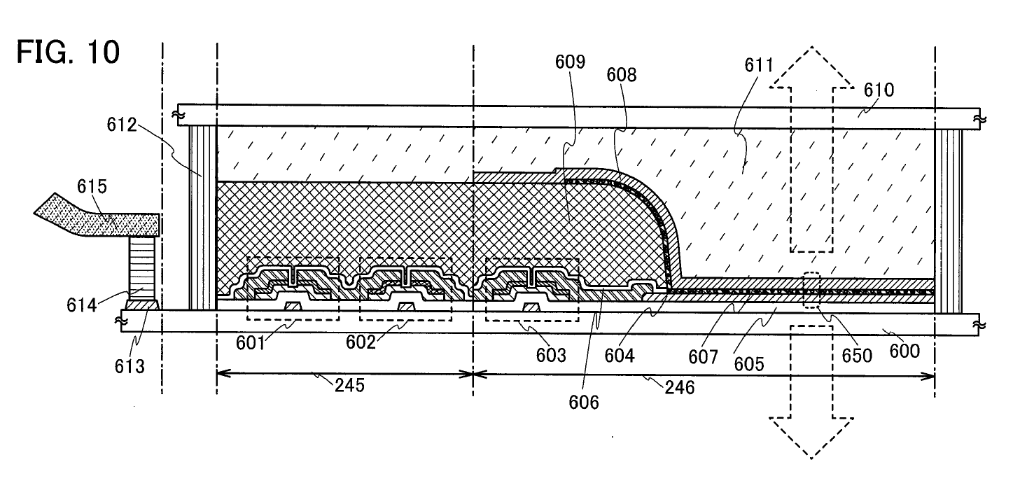

Another embodiment mode of the present invention will be explained with reference to FIG. 10. This embodiment mode shows an example in which, in the display device manufactured in Embodiment Mode 4, a channel-etched type reverse staggered thin film transistor is used as a thin film transistor and the first interlayer insulating layer and the second interlayer insulating layer are not formed. Therefore, the same portions or portions having the similar functions will not be repeatedly explained.

A display device shown in FIG. 10 includes, over a substrate 600, reverse staggered thin film transistors 601 and 602 in a peripheral driver circuit region 245; a reverse staggered thin film transistor 603 in a pixel region 246; and a sealing material 612 in a sealing region. In addition, the display device includes a gate insulating layer 605, an insulating film 606, an insulating layer 609, a light-emitting element 650 which is a stacked layer of a first electrode layer 604, a light-emitting layer 607, and a second electrode layer 608, a filler 611, a sealing substrate 610, a terminal electrode layer 613, an anisotropic conductive layer 614, and an FPC 615.

The light-emitting layer manufactured by using the present invention contains a light-emitting material fixed by a binder. In this embodiment mode, the light-emitting material in a particle state is irradiated with light, the light-emitting material is modified, and crystallinity of the light-emitting material is improved. By light irradiation, dangling bonds of atoms in the light-emitting material are bonded to each other, whereby defects are reduced and distortion is relieved in the light-emitting material. Therefore, a light-emitting material with favorable crystallinity can be used, whereby luminance and light-emitting efficiency of the light-emitting element can be improved and power consumption can also be reduced. Therefore, a display device with high performance and high reliability can be manufactured.

A gate electrode layer, a source electrode layer, and a drain electrode layer of each of the reverse staggered thin film transistors 601, 602, and 603 manufactured in this embodiment mode are formed by a droplet-discharging method. A droplet-discharging method is a method in which a composition having a liquid conductive material is discharged and solidified by drying and baking, whereby a conductive layer and an electrode layer are formed. When a composition including an insulating material is discharged and solidified by drying and baking, an insulating layer can also be formed. Since a component of a display device, such as a conductive layer or an insulating layer can be selectively formed, steps are simplified and material loss can be prevented. Therefore, a display device can be manufactured at low cost with high productivity.

A droplet-discharging means used in a droplet-discharging method is generally a means for discharging liquid droplets, such as a nozzle equipped with a composition discharge outlet, a head having one or a plurality of nozzles, or the like. Each nozzle of the droplet-discharging means is set that: the diameter is 0.02 to 100 μm (preferably less than or equal to 30 μm) and the quantity of component discharge from the nozzle is 0.001 to 100 pl (preferably greater than or equal to 0.1 pl and less than or equal to 40 pl and much preferably less than or equal to 10 pl). The discharge quantity is increased proportionately to the diameter of the nozzle. It is preferable that a distance between an object to be processed and the discharge outlet of the nozzle be as short as possible in order to drip the droplet on a desired position; the distance is preferably set to be 0.1 to 3 mm (much preferably less than or equal to 1 mm).

In the case where a film (e.g., an insulating film or a conductive film) is formed by a droplet-discharging method, the film is formed as follows: a composition containing a film material which is processed into a particle state is discharged, and the composition is fused or welded by baking to be solidified. A film formed by a sputtering method or the like tends to have a columnar structure, whereas the film thus formed by discharging and baking of the composition containing a conductive material tends to have a polycrystalline structure having the large number of grain boundaries.

As the composition to be discharged from the discharge outlet, a conductive material dissolved or dispersed in a solvent is used. The conductive material corresponds to a fine particle or a dispersed nanoparticle of metal such as Ag, Au, Cu, Ni, Pt, Pd, Ir, Rh, W, or Al, metal sulfide such as Cd or Zn, oxide of Fe, Ti, Si, Ge, Zr, Ba, or the like, silver halide, or the like. In addition, the above-described conductive materials may also be used in combination. Although a transparent conducive film transmits light in exposure of a back side because of a light-transmitting property, the transparent conductive film can be used as being a stacked body with a material which does not transmit light. As the transparent conductive film, indium tin oxide (ITO), indium tin oxide containing silicon oxide (ITSO), organic indium, organic tin, zinc oxide, titanium nitride, or the like can be used. Further, indium zinc oxide (IZO) containing zinc oxide (ZnO), zinc oxide (ZnO), ZnO doped with gallium (Ga), tin oxide (SnO₂), indium oxide containing tungsten oxide, indium zinc oxide containing tungsten oxide, indium oxide containing titanium oxide, indium tin oxide containing titanium oxide, or the like may also be used. As for the composition to be discharged from the discharge outlet, it is preferable to use any of the materials of gold, silver, and copper dissolved or dispersed in a solvent, considering specific resistance, and it is much preferable to use silver or copper having low resistance. When silver or copper is used, a barrier film may be provided in addition as a countermeasure against impurities. A silicon nitride film or a nickel boron (NiB) film can be used as the barrier film.

The composition to be discharged is a conductive material dissolved or dispersed in a solvent, which further contains a dispersant or a thermosetting resin. In particular, the thermosetting resin has a function of preventing generation of cracks or uneven baking during baking. Thus, a formed conductive layer may contain an organic material. The organic material that is contained is different depending on heating temperature, atmosphere, and time. This organic material is an organic resin which functions as a thermosetting resin, a solvent, a dispersant, and a coating of a metal particle, or the like; typically, polyimide, acrylic, a novolac resin, a melamine resin, a phenol resin, an epoxy resin, a silicon resin, a furan resin, a diallyl phthalate resin, or other organic resins can be given as examples.

In addition, a particle with a plurality of layers, in which a conductive material is coated with another conductive material, may also be used. For example, a particle with a three-layer structure in which copper is coated with nickel boron (NiB) and the nickel boron is further coated with silver, may be used. As for the solvent, esters such as butyl acetate or ethyl acetate, alcohols such as isopropyl alcohol or ethyl alcohol, an organic solvent such as methyl ethyl ketone or acetone, or water is used. The viscosity of the composition is preferably less than or equal to 20 mPa·s (cp), which prevents the composition from drying, and enables the composition to be discharged smoothly from the discharge outlet. The surface tension of the composition is preferably less than or equal to 40 mN/m. However, the viscosity of the composition and the like may be appropriately controlled depending on a solvent to be used or an intended purpose. For example, the viscosity of a composition in which ITO, organic indium, or organic tin is dissolved or dispersed in a solvent may be set to be 5 to 20 mPa·s, the viscosity of a composition in which silver is dissolved or dispersed in a solvent may be set to be 5 to 20 mPa·s, and the viscosity of a composition in which gold is dissolved or dispersed in a solvent may be set to be 5 to 20 mPa·s.

Further, the conductive layer may also be formed by a plurality of stacked conductive materials. In addition, the conductive layer may be formed first by a droplet-discharging method using silver as a conductive material and may be then plated with copper or the like. The plating may be performed by electroplating or a chemical (electroless) plating method. The plating may be performed by immersing a substrate surface in a container filled with a solution containing a plating material; alternatively, the solution containing a plating material may be applied to the substrate placed obliquely (or vertically) so as to flow the solution containing a plating material on the substrate surface. When the plating is performed by application of a solution to the substrate placed obliquely, there is an advantage of miniaturizing a process apparatus.

The diameter of a particle of the conductive material is preferably as small as possible for the purpose of preventing nozzles from being clogged and for manufacturing a minute pattern, although it depends on the diameter of each nozzle, a desired shape of a pattern, and the like. Preferably, the diameter of the particle of the conductive material is less than or equal to 0.1 μm. The composition is formed by a known method such as an electrolyzing method, an atomizing method, or a wet reduction method, and the particle size is generally about 0.01 to 10 μm. When a gas evaporation method is employed, the size of nanoparticles protected by a dispersant is as minute as about 7 nm, and when the surface of each particle is covered with a coating, the nanoparticles do not aggregate in the solvent and are stably dispersed in the solvent at room temperature, and behave similarly to liquid. Accordingly, it is preferable to use a coating.

In addition, the step of discharging the composition may be performed under reduced pressure. When the step is performed under reduced pressure, an oxide film or the like is not formed on the surface of the conductive material, which is preferable. After the composition is discharged, either drying or baking or both of them are performed. Both the drying step and baking step are heat treatment; however, for example, drying is performed at 100° C. for 3 minutes and baking is performed at 200 to 350° C. for 15 to 60 minutes, and they are different in purpose, temperature, and time period. The steps of drying and baking are performed under normal pressure or under reduced pressure, by laser beam irradiation, rapid thermal annealing, heating using a heating furnace, or the like. It is to be noted that the timing of each heat treatment is not particularly limited. The substrate may be heated in advance to favorably perform the steps of drying and baking, and the temperature at that time is, although it depends on the material of the substrate or the like, generally 100 to 800° C. (preferably, 200 to 350° C.). Through these steps, nanoparticles are made in contact with each other and fusion and welding are accelerated since a peripheral resin is hardened and shrunk, while the solvent in the composition is volatilized or the dispersant is chemically removed.

A continuous wave or pulsed gas laser or solid-state laser may be used for laser beam irradiation. An excimer laser, a YAG laser, or the like can be used as the former gas laser. A laser using a crystal of YAG, YVO₄, GdVO₄, or the like which is doped with Cr, Nd, or the like can be used as the latter solid-state laser. It is preferable to use a continuous wave laser in consideration of the absorptance of a laser beam. Moreover, a laser irradiation method in which pulsed and continuous wave lasers are combined may be used. It is preferable that the heat treatment by laser beam irradiation be instantaneously performed within several microseconds to several tens of seconds so as not to damage the substrate 600, depending on heat resistance of the substrate 600. Rapid thermal annealing (RTA) is carried out by raising the temperature rapidly and heating the substrate instantaneously for several microseconds to several minutes with the use of an infrared lamp or a halogen lamp which emits ultraviolet to infrared light in an inert gas atmosphere. Since this treatment is performed instantaneously, only an outermost thin film can be heated and the lower layer of the film is not adversely affected. In other words, even a substrate having low heat resistance such as a plastic substrate is not adversely affected.

After the conductive layer or the insulating layer is formed by discharge of a liquid composition by a droplet-discharging method, the surface thereof may be planarized by pressing with pressure to enhance planarity. As a pressing method, concavity and convexity may be reduced by scanning of a roller-shaped object on the surface, or the surface may be pressed with a flat plate-shaped object. A heating step may be performed at the time of pressing. Alternatively, the concavity and convexity of the surface may be removed with an air knife after the surface is softened or melted with a solvent or the like. A CMP method may also be used for polishing the surface. This step can be employed in planarizing of a surface when concavity and convexity are generated by a droplet-discharging method.

In this embodiment mode, an amorphous semiconductor is used as a semiconductor layer and a semiconductor layer having one conductive type may be formed as needed. In this embodiment mode, an amorphous n-type semiconductor layer as a semiconductor layer having one conductive type is stacked over a semiconductor layer. Further, an NMOS structure of an n-channel TFT in which an n-type semiconductor layer is formed, a PMOS structure of a p-channel TFT in which a p-type semiconductor layer is formed, and a CMOS structure of an n-channel TFT and a p-channel TFT can be manufactured. In this embodiment mode, the reverse staggered thin film transistors 601 and 603 are formed of n-channel TFTs, and the reverse staggered thin film transistor 602 is formed of a p-channel TFT, whereby the reverse staggered thin film transistors 601 and 602 form a CMOS structure in the peripheral driver circuit region 245.

Moreover, in order to impart conductivity, an element imparting conductivity is added by doping and an impurity region is formed in the semiconductor layer; therefore, an n-channel TFT and a p-channel TFT can be formed. Instead of forming an n-type semiconductor layer, conductivity may be imparted to the semiconductor layer by plasma treatment with a PH₃ gas.

Further, the semiconductor layer can be formed using an organic semiconductor material by a printing method, a spray method, a spin coating method, a droplet-discharging method, a dispenser method, or the like. In this case, the aforementioned etching step is not required; therefore, the number of steps can be reduced. As an organic semiconductor, a low molecular material, a high molecular material, and the like can be used, and a material such as an organic pigment and a conductive high molecular material can be used as well. As the organic semiconductor material used in the present invention, a high molecular material of a π electron conjugated system of which a skeleton is composed of conjugated double bonds is preferable. Typically, a soluble high molecular material such as polythiophene, polyfluorene, poly(3-alkylthiophene), a polythiophene derivative, or pentacene can be used.

The structure as described in this embodiment mode can be applied to the structure of the light-emitting element that can be used in the present invention.

This embodiment mode can be freely combined with each of Embodiment Modes 1 to 5.

By light irradiation to the light-emitting material used in the present invention, dangling bonds of atoms in the light-emitting material are bonded to each other, whereby defects are reduced and crystallinity is improved. In addition, through the use of a light-emitting element using such a light-emitting material with favorable crystallinity, low-voltage driving, high luminance, and high light-emitting efficiency can be obtained.

Accordingly, by using the present invention, a display device with low power consumption, high performance, and high reliability can be manufactured at low cost with high productivity.

### Embodiment Mode 7

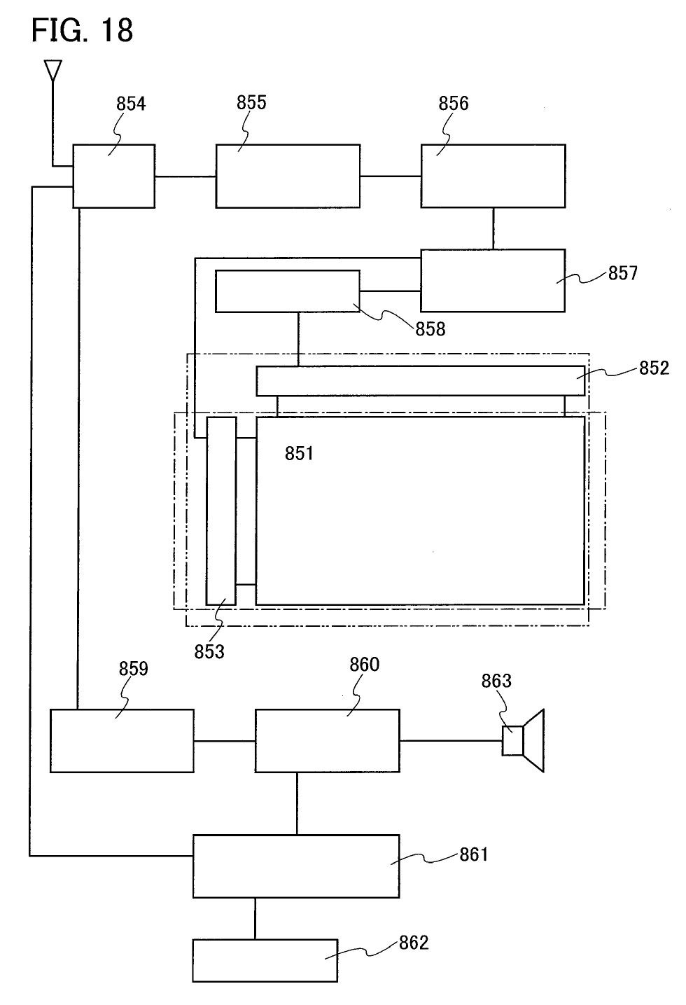

By the display device formed by the present invention, a television device can be completed. FIG. 18 is a block diagram showing a major structure of a television device (in this embodiemnt mode, an EL television device). In a display panel, there are the case where only a pixel portion is formed in such a structure as shown in FIG. 16A and a scanning line driver circuit and a signal line driver circuit are mounted by a TAB method as shown in FIG. 17B, the case where they are mounted by a COG method as shown in FIG. 17A, the case where TFTs are each formed of SAS as shown in FIG. 16B, the pixel portion and the scanning line driver circuit are integrated over the substrate, and the signal line driver circuit is mounted as a driver IC separately, and the case where the pixel portion, the signal line driver circuit, and the scanning line driver circuit are integrated over the substrate as shown in FIG. 16C, or the like. The display panel may have any of the aforementioned modes. In addition, a signal line driver circuit 852, a scanning line driver circuit 853 and a pixel portion 851 may have any structure.

As another configuration of an external circuit, on an input side of video signals, a video signal amplifier circuit 855 which amplifies a video signal among signals received by a tuner 854, a video signal processing circuit 856 which converts a signal output from the video signal amplifier circuit 855 into a color signal corresponding to each of red, green, and blue, a control circuit 857 which converts the video signal into an input specification of the driver IC, and the like are provided. The control circuit 857 outputs signals to the scanning line side and the signal line side. In the case of digital driving, a signal dividing circuit 858 is provided on the signal line side so that input digital signals are divided into m pieces to be supplied.

Among the signals received by the tuner 854, audio signals are transmitted to an audio signal amplifier circuit 859 of which output is supplied to a speaker 863 through an audio signal processing circuit 860. A control circuit 861 receives control data such as a receiving station (receiving frequency) and volume from an input unit 862 and transmits signals to the tuner 854 and the audio signal processing circuit 860.

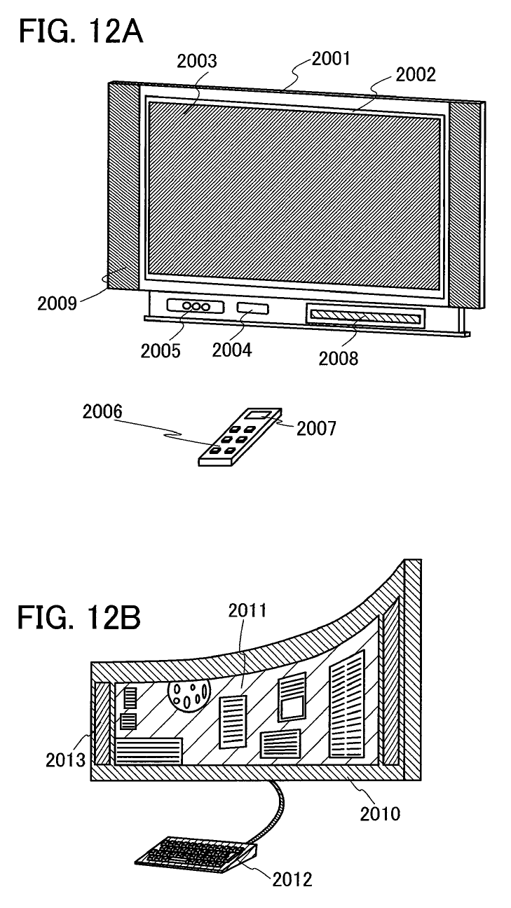

A display module is incorporated in a housing as shown in FIGS. 12A and 12B, whereby a television device can be completed. A display panel in which components up to an FPC are set as shown in FIGS. 7A and 7B is generally called an EL display module. Therefore, by using the EL display module as shown in FIGS. 7A and 7B, an EL television device can be completed. A main screen 2003 is formed by using the display module, and as other attachment systems, a speaker portion 2009, an operation switch, and the like are provided. In this manner, a television device can be completed by the present invention.

In addition, through the use of a retardation film and a polarizing plate, reflected light of light incident from an external portion may be blocked. In the case of a top emission display device, an insulating layer serving as a partition wall may be colored to be used as a black matrix. The partition wall can be formed by a droplet-discharging method or the like as well, using a pigment-based black resin or a resin material such as polyimide mixed with carbon black or the like, or a stacked layer thereof. A partition wall may be formed by discharge of different materials in the same region a plurality of times by a droplet-discharging method. As the retardation film, a quarter wave plate or a half wave plate may be used, and the display module may be designed so as to be able to control light. As the structure, a TFT element substrate, a light-emitting element, a sealing substrate (sealing material), a retardation film (a quarter wave plate or a half wave plate), and a polarizing plate are sequentially stacked, where light emitted from the light-emitting element is transmitted therethrough and emitted to an external portion from a polarizing plate side. The polarizing plate, the retardation film, and the like may also have a stacked structure. The retardation film and the polarizing plate may be provided on a side to which light is emitted or may be provided on both sides in the case of a dual emission display device in which light is emitted to the both sides. In addition, an anti-reflective film may be provided on the outer side of the polarizing plate. Accordingly, an image with higher resolution and precision can be displayed.

As shown in FIG. 12A, a display panel 2002 using a display element is incorporated in a housing 2001. General television broadcast can be received by a receiver 2005. Further, by connection to a communication network in a wired or wireless manner through a modem 2004, one way (transmitter to receiver) or two-way (between transmitter and receiver or between receivers) data communication is possible. The television device can be operated by using a switch incorporated in the housing or a separate remote control device 2006. The remote control device may be provided with a display portion 2007 which displays data to be output.

In the television device, a sub-screen 2008 may be formed using a second display panel in addition to the main screen 2003, which has a structure to display a channel, volume, or the like. In this structure, the main screen 2003 may be formed using an EL display panel with a superior viewing angle while the sub-screen may be formed using a liquid crystal display panel which can perform display with low power consumption. To give priority to low power consumption, the main screen 2003 may be formed using a liquid crystal display panel and the sub-screen may be formed using an EL display panel so as to be capable of blinking. By using the present invention, a highly reliable display device can be manufactured even by using a large substrate with a lot of TFTs and electronic components.

FIG. 12B is a television device having a large display portion with the size of, for example, 20 to 80 inches, including a housing 2010, a keyboard portion 2012 as an operation portion, a display portion 2011, a speaker portion 2013, and the like. The present invention is applied to manufacturing of the display portion 2011. The display portion shown in FIG. 12B is formed of a substance which can be curved; therefore, the television device has a curved display portion. In this manner, the shape of the display portion can be freely designed; therefore, a television device with a desired shape can be manufactured.

In accordance with the present invention, a display device can be manufactured through simplified steps; therefore, the cost can be reduced. As a result, a television device can be manufactured at low cost even with a large display portion by using the present invention. Thus, a television device with high performance and high reliability can be manufactured with high yield.

It is needless to say that the present invention is not limited to a television device and can be used for various applications as a large display medium, such as an information display board at train stations, airports, and the like, and an advertisement board on the street as well as a monitor of a personal computer.

This embodiment mode can be used by being combined with each of Embodiment Modes 1 to 6.

### Embodiment Mode 8

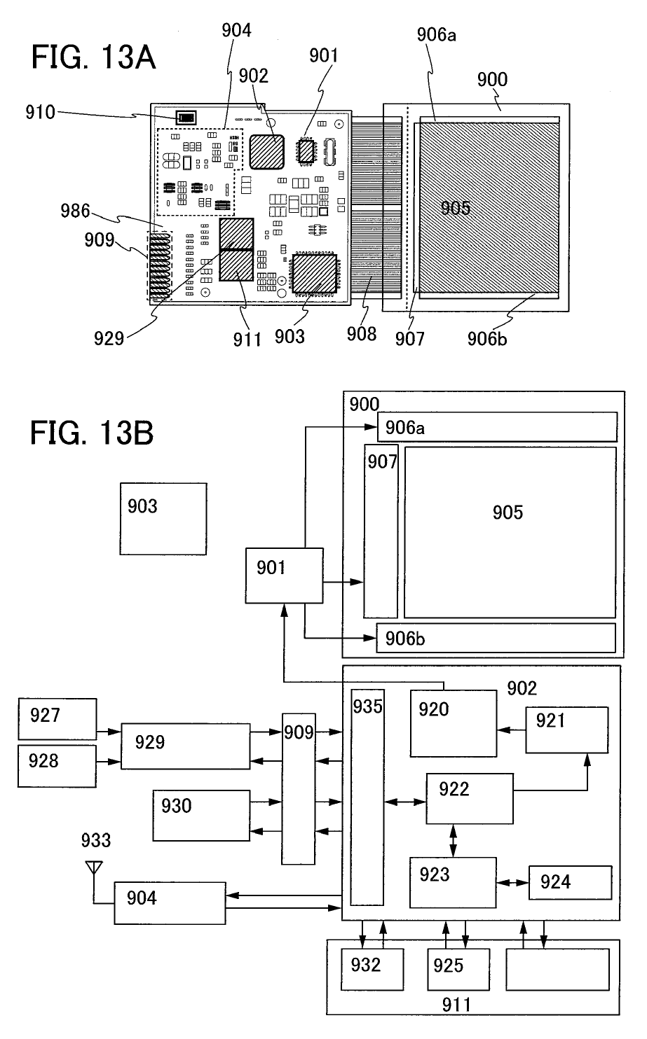

This embodiment mode will be explained with reference to FIGS. 13A and 13B. This embodiment mode will show an example of a module using a panel including a display device manufactured in Embodiment Modes 3 to 7.

A module of an information terminal shown in FIG. 13A includes a printed wiring board 986 over which a controller 901, a central processing unit (CPU) 902, a memory 911, a power source circuit 903, an audio processing circuit 929, a transmission/reception circuit 904, and other elements such as a resistor, a buffer, and a capacitor are mounted. In addition, a panel 900 is connected to the printed wiring board 986 through a flexible wiring circuit (FPC) 908.

The panel 900 is provided with a pixel portion 905 having a light-emitting element in each pixel, a first scanning line driver circuit 906a and a second scanning line driver circuit 906b which select a pixel included in the pixel portion 905, and a signal line driver circuit 907 which supplies a video signal to the selected pixel.

Various control signals are input and output through an interface (I/F) portion 909 provided over the printed wiring board 986. An antenna port 910 for transmitting and receiving signals to/from an antenna is provided over the printed wiring board 986.

It is to be noted that, in this embodiment mode, the printed wiring board 986 is connected to the panel 900 through the FPC 908; however, the present invention is not limited to this structure. The controller 901, the audio processing circuit 929, the memory 911, the CPU 902, or the power source circuit 903 may be directly mounted on the panel 900 by a COG (Chip on Glass) method. Moreover, various elements such as a capacitor and a buffer provided over the printed wiring board 986 prevent a noise in power source voltage or a signal and a rounded rise of a signal.

FIG. 13B is a block diagram of the module shown in FIG. 13A. A module includes a VRAM 932, a DRAM 925, a flash memory 926, and the like as the memory 911. The VRAM 932 stores image data displayed on the panel, the DRAM 925 stores image data or audio data, and the flash memory stores various programs.

The power source circuit 903 generates power source voltage applied to the panel 900, the controller 901, the CPU 902, the audio processing circuit 929, the memory 911, and the transmission/reception circuit 904. Moreover, depending on the specifications of the panel, a current source is provided in the power source circuit 903 in some cases.

The CPU 902 includes a control signal generating circuit 920, a decoder 921, a register 922, an arithmetic circuit 923, a RAM 924, an interface 935 for the CPU, and the like. Various signals input to the CPU 902 through the interface 935 are input to the arithmetic circuit 923, the decoder 921, and the like after once being held in the register 922. The arithmetic circuit 923 operates based on the input signal and specifies an address to send various instructions. On the other hand, a signal input to the decoder 921 is decoded and input to the control signal generating circuit 920. The control signal generating circuit 920 generates a signal including various instructions based on the input signal and sends it to the address specified by the arithmetic circuit 923, which are specifically the memory 911, the transmission/reception circuit 904, the audio processing circuit 929, the controller 901, and the like.

The memory 911, the transmission/reception circuit 904, the audio processing circuit 929, and the controller 901 operate in accordance with respective received instructions. The operations will be briefly explained below.

The signal input from an input unit 930 is transmitted to the CPU 902 mounted on the printed wiring board 986 through the interface 909. The control signal generating circuit 920 converts the image data stored in the VRAM 932 into a predetermined format in accordance with the signal transmitted from the input unit 930 such as a pointing device and a keyboard, and then transmits it to the controller 901.

The controller 901 processes a signal including image data transmitted from the CPU 902 in accordance with the specifications of the panel and supplies it to the panel 900. The controller 901 generates a Hsync signal, a Vsync signal, a clock signal CLK, alternating voltage (AC Cont), and a switching signal L/R and supplies them to the panel 900 based on the power source voltage input from the power source circuit 903 and various signals input from the CPU 902.

In the transmission/reception circuit 904, a signal transmitted and received as an electric wave by the antenna 933 is processed. Specifically, high frequency circuits such as an isolator, a band path filter, a VCO (Voltage Controlled Oscillator), an LPF (Low Pass Filter), coupler, and balan are included. Among the signals transmitted and received by the transmission/reception circuit 904, signals including audio data are transmitted to the audio processing circuit 929 in accordance with an instruction transmitted from the CPU 902.

The signals including audio data transmitted in accordance with the instruction from the CPU 902 are demodulated into audio signals in the audio processing circuit 929 and transmitted to a speaker 928. The audio signal transmitted from a microphone 927 is modulated in the audio processing circuit 929 and transmitted to the transmission/reception circuit 904 in accordance with the instruction from the CPU 902.

The controller 901, the CPU 902, the power source circuit 903, the audio processing circuit 929, and the memory 911 can be incorporated as a package of this embodiment mode. This embodiment mode can be applied to any circuit besides high frequency circuits such as an isolator, a band path filter, a VCO (Voltage Controlled Oscillator), an LPF (Low Pass Filter), coupler, and balan.

### Embodiment Mode 9

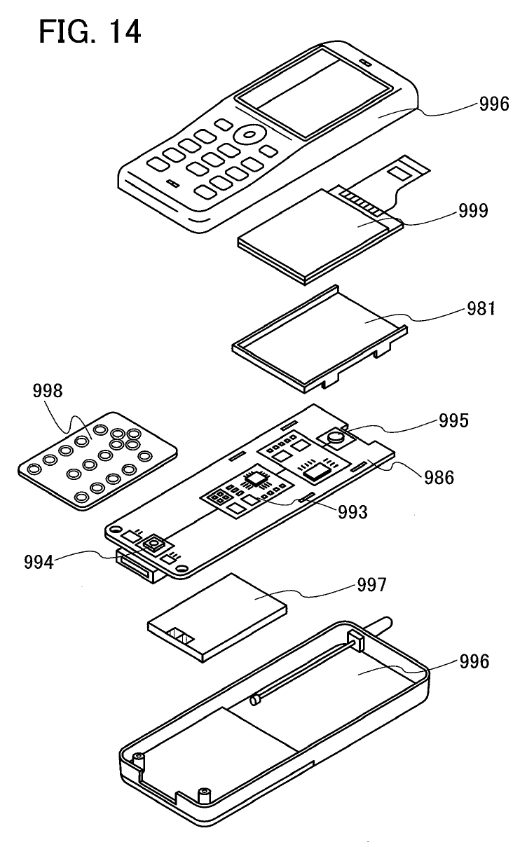

This embodiment mode will be explained with reference to FIG. 14. FIG. 14 shows one mode of a compact phone (mobile phone) including the module manufactured in Embodiment Mode 8, which operates wirelessly and can be carried. A panel 900 is detachably incorporated in a housing 981 so as to be easily combined with a module 999. The shape and the size of the housing 981 can be appropriately changed in accordance with an electronic device into which the module is incorporated.

The housing 981 in which the panel 900 is fixed is fitted to a printed wiring board 986 and set up as a module. A plurality of semiconductor devices which are packaged are mounted on the printed wiring board 986. The plurality of semiconductor devices mounted on the printed wiring board 986 have any function of a controller, a central processing unit (CPU), a memory, a power source circuit, and other elements such as a resistor, a buffer, and a capacitor. Moreover, an audio processing circuit including a microphone 994 and a speaker 995 and a signal processing circuit 993 such as a transmission/reception circuit are provided. The panel 900 is connected to the printed wiring board 986 through an FPC 908.

The module 999, the housing 981, the printed wiring board 986, an input unit 998, and a battery 997 are stored in a housing 996. The pixel portion of the panel 900 is arranged so that it can be seen through a window formed in the housing 996.

The housing 996 shown in FIG. 14 is shown as an example of an exterior shape of a mobile phone. However, an electronic device of this embodiment mode can be changed into various modes in accordance with functions and intended purpose. In the following embodiment mode, examples of the modes will be explained.

### Embodiment Mode 10

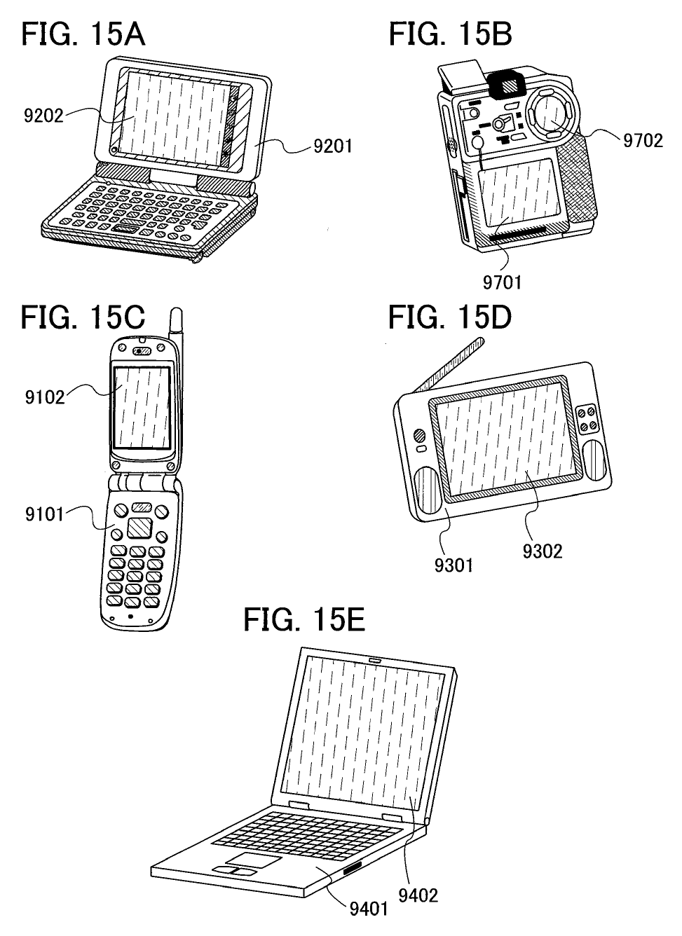

As an electronic device according to the present invention, an image reproducing device such as a television device (also referred to simply as a television or a television receiver), a camera such as a digital camera or a digital video camera, a mobile phone set (also referred to simply as a mobile phone or a cell-phone), a portable information terminal such as a PDA, a portable game machine, a monitor for a computer, a computer, an audio reproducing device such as a car audio system, or a home game machine can be given. The specific examples will be explained with reference to FIGS. 15A to 15E.

A portable information terminal device shown in FIG. 15A includes a main body 9201, a display portion 9202, and the like. The display device of the present invention can be applied to the display portion 9202. Accordingly, a portable information terminal device with low power consumption, high image quality, and high reliability can be provided.

A digital video camera shown in FIG. 15B includes display portions 9701 and 9702, and the like. The display device of the present invention can be applied to the display portion 9701. Accordingly, a digital video camera with low power consumption, high image quality, and high reliability can be provided.

A mobile phone shown in FIG. 15C includes a main body 9101, a display portion 9102, and the like. The display device of the present invention can be applied to the display portion 9102. Accordingly, a mobile phone with low power consumption, high image quality, and high reliability can be provided.

A portable television device shown in FIG. 15D includes a main body 9301, a display portion 9302, and the like. The display device of the present invention can be applied to the display portion 9302. Accordingly, a portable television device with low power consumption, high image quality, and high reliability can be provided. In addition, the display device of the present invention can be applied to the broad range of television devices from a small-size one mounted on a portable terminal such as a mobile phone to a medium-size one which can be carried, in addition, a large-size one (for example, greater than or equal to 40 inches).

A portable computer shown in FIG. 15E includes a main body 9401, a display portion 9402, and the like. The display device of the present invention can be applied to the display portion 9402. Accordingly, a portable computer with low power consumption, high image quality, and high reliability can be provided.

In this manner, by the display device of the present invention, an electronic device with lower power consumption, higher image quality, and higher reliability can be provided. This embodiment mode can be freely combined with the above embodiment modes.

This application is based on Japanese Patent Application serial no. 2006-034452 filed on Feb. 10, 2006, in Japan Patent Office, the entire contents of which are hereby incorporated by reference.

What is claimed is:

1. A method for manufacturing a light emitting device, comprising the steps of:
irradiating a light-emitting material with light;
dispersing the light-emitting material irradiated with light in a solution containing a binder;
disposing the solution containing the light-emitting material irradiated with light and the binder on a first electrode layer and forming a light-emitting layer containing the light-emitting material irradiated with light and the binder; and
forming a second electrode layer over the light-emitting layer.

2. The method for manufacturing a light emitting device according to claim 1, wherein an insulating layer is formed between the first electrode layer and the light-emitting layer.

3. The method for manufacturing a light emitting device according to claim 1, wherein the solution is applied on the first electrode layer by a printing method.

4. The method for manufacturing a light emitting device according to claim 1, wherein the light-emitting material contains a host material and an impurity element.

5. The method for manufacturing a light emitting device according to claim 1, wherein the binder is formed by using an organic resin.

6. A method for manufacturing a light emitting device, comprising the steps of:
irradiating a light-emitting material in a particle state with a laser beam;
dispersing the light-emitting material in a particle state irradiated with the laser beam in a solution containing a binder;
disposing the solution containing the light-emitting material in a particle state irradiated with the laser beam and the binder on a first electrode layer and forming a light-emitting layer containing the light-emitting material in a particle state irradiated with the laser beam and the binder; and
forming a second electrode layer over the light-emitting layer.

7. The method for manufacturing a light emitting device according to claim 6, wherein an insulating layer is formed between the first electrode layer and the light-emitting layer.

8. The method for manufacturing a light emitting device according to claim 6, wherein the solution is applied on the first electrode layer by a printing method.

9. The method for manufacturing a light emitting device according to claim 6, wherein the light-emitting material contains a host material and an impurity element.

10. The method for manufacturing a light emitting device according to claim 6, wherein the binder is formed by using an organic resin.

11. A method for manufacturing a light emitting device, comprising the steps of:
irradiating a light-emitting material with a laser beam;
dispersing the light-emitting material irradiated with the laser beam in a solution containing a binder;
disposing the solution containing the light-emitting material irradiated with the laser beam and the binder on a first electrode layer, performing baking, and forming a light-emitting layer containing the light-emitting material irradiated with the laser beam and the binder; and
forming a second electrode layer over the light-emitting layer.

12. The method for manufacturing a light emitting device according to claim 11, wherein an insulating layer is formed between the first electrode layer and the light-emitting layer.

13. The method for manufacturing a light emitting device according to claim 11, wherein the solution is applied on the first electrode layer by a printing method.

14. The method for manufacturing a light emitting device according to claim 11, wherein the light-emitting material contains a host material and an impurity element.

15. The method for manufacturing a light emitting device according to claim 11, wherein the binder is formed by using an organic resin.

16. A method for manufacturing a light emitting device, comprising the steps of:
irradiating a light-emitting material in a particle state with a laser beam;
dispersing the light-emitting material in a particle state irradiated with the laser beam in a solution containing a binder;
disposing the solution containing the light-emitting material in a particle state irradiated with the laser beam and the binder on a first electrode layer, performing baking, and forming a light-emitting layer containing the light-emitting material in a particle state irradiated with the laser beam and the binder; and
forming a second electrode layer over the light-emitting layer.

17. The method for manufacturing a light emitting device according to claim 16, wherein an insulating layer is formed between the first electrode layer and the light-emitting layer.

18. The method for manufacturing a light emitting device according to claim 16, wherein the solution is applied on the first electrode layer by a printing method.

19. The method for manufacturing a light emitting device according to claim 16, wherein the light-emitting material contains a host material and an impurity element.

20. The method for manufacturing a light emitting device according to claim 16, wherein the binder is formed by using an organic resin.
